(19) United States
(12) Patent Application Publication
(10) Pub. No.: US 2016/0293421 A1
(43) Pub. Date: Oct. 6, 2016

(54) METHOD OF MANUFACTURING SEMICONDUCTOR DEVICE AND RECORDING MEDIUM

(71) Applicant: HITACHI KOKUSAI ELECTRIC INC., Tokyo (JP)

(72) Inventors: Kazuhiro HARADA, Toyama-shi (JP); Arito OGAWA, Toyama-shi (JP); Motomu DEGAI, Toyama-shi (JP); Masahito KITAMURA, Toyama-shi (JP); Hiroshi ASHIHARA, Toyama-shi (JP)

(73) Assignee: HITACHI KOKUSAI ELECTRIC INC., Tokyo (JP)

(21) Appl. No.: 15/075,707

(22) Filed: Mar. 21, 2016

(30) Foreign Application Priority Data
Mar. 30, 2015 (JP) 2015-069600

(51) Int. Cl. H01L 21/033; H01L 21/28

(52) U.S. Cl. CPC H01L 21/0338; H01L 21/0332; H01L 21/0335; H01L 21/0337; H01L 21/28123

(57) ABSTRACT

A method of manufacturing a semiconductor device includes forming a metal-containing film including a first element that is a metal element and a second element by performing a predetermined number of times in a time-division manner a cycle of supplying an organic metal source gas containing the first element to a substrate, supplying a halogen-based metal source gas containing the first element to the substrate and supplying a reaction gas, which contains the second element and which reacts with the first element, to the substrate, wherein a value of film stress of the metal-containing film is controlled by controlling at least one value of a supply flow rate and a supply time of the organic metal source gas in the act of supplying an organic metal source gas.

### CROSS-REFERENCE TO RELATED APPLICATION

This application is based upon and claims the benefit of priority from Japan Patent Application No. 2015-069600, filed on Mar. 30, 2015, the entire content of which is incorporated herein by reference.

### TECHNICAL FIELD

The present disclosure relates to a method of manufacturing a semiconductor device and a recording medium.

### BACKGROUND

Recently, as semiconductor devices such as metal-oxide semiconductor field effect transistors (MOSFETs) have been highly integrated and have become highly efficient, devices have become miniaturized in shape or complicated, thereby requiring a finer microfabrication technology. In a dry etching method that is one of the methods used in the microfabrication technology, after a film that is not etched is covered by a film called a mask, a film which is not covered by the mask is removed. As the mask, a conductive thin film may be used as a hard mask. As the conductive thin film, a metal nitride film (e.g., a titanium nitride film (TiN film)) is employed as a metal film (metal gate electrode).

When a conductive thin film is used as a hard mask, a pattern may be bent due to film stress of a thin film. Thus, the film stress needs to be reduced. Although being often used as a barrier film (barrier metal), the conductive thin film has been required to have increased barrier properties thereof since films become thinner in line with high integration and high performance.

### SUMMARY

The present disclosure provides some embodiments of a technique capable of increasing barrier properties by reducing film stress of a conductive thin film.

According to one embodiment of the present disclosure, there is provided a method of manufacturing a semiconductor device or a substrate processing method, including forming a metal-containing film including a first element that is a metal element and a second element by performing a predetermined number of times in a time-division manner a cycle including: supplying an organic metal source gas containing the first element to a substrate; supplying a halogen-based metal source gas containing the first element to the substrate; and supplying a reaction gas, which contains the second element and which reacts with the first element, to the substrate, wherein a value of film stress of the metal-containing film is controlled by controlling at least one value of a supply flow rate and a supply time of the organic metal source gas in the act of supplying an organic metal source gas.

### BRIEF DESCRIPTION OF THE DRAWINGS

FIG. 1 is a schematic configuration view of a processing furnace of a substrate processing apparatus suitably used in an embodiment of the present disclosure, which illustrates a longitudinal sectional view of a processing furnace part.

FIG. 2 is a cross-sectional view taken along line A-A of FIG. 1.

FIG. 3 is a block diagram illustrating a configuration of a controller of the substrate processing apparatus illustrated in FIG. 1.

FIG. 4 is a view illustrating a sequence in a first embodiment of the present disclosure.

FIGS. 5A to 5F are views illustrating a technique of forming a pattern on a substrate through a double patterning method, wherein FIG. 5A illustrates a state where a first resist solvent is applied onto a hard mask, FIG. 5B illustrates a state where a first resist pattern is formed, FIG. 5C illustrates a state where a barrier film is formed, FIG. 5D illustrates a state where a second resist solution is applied, and FIG. 5E illustrates a state where a second resist pattern 603b is formed.

FIG. 6 is a view illustrating a sequence in a second embodiment of the present disclosure.

FIG. 7 is a view illustrating a sequence in a third embodiment of the present disclosure.

FIG. 8 is a view illustrating a sequence in a fourth embodiment of the present disclosure.

FIG. 9 is a view illustrating a sequence in a fifth embodiment of the present disclosure.

FIG. 10 is a view illustrating a sequence in a sixth embodiment of the present disclosure.

FIG. 11 is a view illustrating film formation rates in Experimental Examples 1 and 2 and Comparative Example.

FIG. 12 is a view illustrating a relationship between a supply time of TDEAT and Ti intensity.

FIG. 13A illustrates a composition ratio of a TiN film formed in Experimental Example 1 and FIG. 13B illustrates a composition ratio of a TiN film formed in Experimental Example 2.

FIG. 14 is a view illustrating crystallinity of TiN films formed in Experimental Examples 1 and 2.

FIGS. 15A and 15B are views illustrating a method for manufacturing a capacitor used in calculating a work function, wherein FIG. 15A is a flowchart and FIG. 15B is a schematic view of the capacitor.

FIG. 16 is a view illustrating a relationship between EOT of an equivalent film thickness of TiN films formed in Experimental Examples 1 and 2 and effective work function.

FIG. 17 is a schematic configuration view of a processing furnace of a substrate processing apparatus appropriately used in another embodiment of the present disclosure, which illustrates a longitudinal vertical sectional view of a processing furnace part.

FIG. 18 is a schematic configuration view of a processing furnace of a substrate processing apparatus suitably used in another embodiment of the present disclosure, which illustrates a longitudinal vertical sectional view of a processing furnace part.

### DETAILED DESCRIPTION

In the case of forming a TiN film, which is a metal nitride film, on a substrate as a conductive thin film that is used as a hard mask, a method of forming a TiN film using a halogen-based Ti-containing gas as a Ti-containing gas and a nitrogen (N)-containing gas can be used. Inventors studied the case and found that film stress could be lowered by using an organic Ti-containing gas, in addition to the halogen-based Ti-containing gas, as a Ti-containing gas. As described later, it can be seen that the case in which the organic Ti-containing gas is added as the Ti-containing gas has an increased film formation rate and reduced film density, compared with the case in which only the halogen-based Ti-containing gas is used as the Ti-containing gas. It is considered that this is because, as described later, the organic Ti-containing gas is adsorbed onto the substrate in a state of containing carbon (C), nitrogen (N), or the like which is included in an amino ligand, and thus, film density is lowered. It is also considered that this is because, as described later, the organic Ti-containing gas is adsorbed onto the substrate in a state of containing C, N, or the like which is included in the amino ligand, and thus, a thickness of the adsorbed layer is increased. When the film density is lowered, the film stress is lowered. Thus, it is possible to lower the film stress by forming a TiN film by using the organic Ti-containing gas, in addition to the halogen-based Ti-containing gas.

Further, the inventors found that even though a supply time of the organic TI-containing gas is lengthened, the saturated adsorption of the organic TI-containing gas does not occur while an adsorbed film thickness is increased as the supply time is lengthened, as described later. Thus, in forming a TiN film, it is possible to control the film stress of the TiN film by adjusting a ratio (balance) between a thickness of the Ti-containing layer resulting from the organic Ti-containing gas and the thickness of the Ti-containing layer resulting from the halogen-based Ti-containing gas. For example, in forming a TiN film, the film stress of the TiN film may be lowered by setting the Ti-containing layer resulting from the organic Ti-containing gas to be thicker than the Ti-containing layer resulting from the halogen-based Ti-containing gas. That is, in forming a TiN film, the film stress of the TiN film may be controlled by adjusting a ratio (balance) between a supply flow rate and/or a supply time of the organic Ti-containing gas and a supply flow rate and/or a supply time of the halogen-based Ti-containing gas. Further, in order to increase a thickness of the Ti-containing layer resulting from the organic Ti-containing gas, it may also be effective to adjust a ratio (balance) between a supply flow rate and/or a supply time of the organic Ti-containing gas and a supply flow rate and/or a supply time of an N-containing gas, when forming a TiN film. For example, by increasing the supply flow rate and/or the supply time of the organic Ti-containing gas, the thickness of the Ti-containing layer resulting from the organic Ti-containing gas can be increased, the density of the TiN film is lowered, and the film stress can be lowered. Conversely, by increasing the supply flow rate and/or the supply time of the N-containing gas, the density of the TiN film can be increased and the film stress can be increased.

In addition, the TiN film may be used as a barrier film, but it is required for the TiN film to be thinned in line with high integration and high performance of semiconductor devices. On the other hand, when the TiN film is thinned, barrier properties thereof are lowered. Thus, a thinned film having high barrier properties is required. As described later, the inventors found that, for example, in forming a TiN film as a metal nitride film on a substrate, when the TiN film is formed by using a halogen-based Ti-containing gas as a Ti-containing gas and a nitrogen (N)-containing gas, the crystallinity of the TiN film is a columnar structure in many cases. When a TiN film having a columnar structure is used as a barrier film, it may show the lack (weakness) of the barrier properties against diffusion from an upper layer thereof. The inventors studied the case and found that the crystallinity of the TiN film obtained by using the organic Ti-containing gas, in addition to the halogen-based Ti-containing gas, as the Ti-containing gas, could be changed to be close to an amorphous state, thereby enhancing the barrier properties of the TiN film. The crystallinity of the obtained TiN film is closer to an amorphous state as the Ti-containing layer resulting from the organic Ti-containing gas is further thickened. Thus, it is possible to control the barrier properties of the TiN film by adjusting a ratio (balance) between a thickness of the Ti-containing layer resulting from the organic Ti-containing gas and a thickness of the Ti-containing layer resulting from the halogen-based Ti-containing gas. That is, in forming a TiN film, it is possible to control the barrier properties of the TiN film by adjusting a ratio (balance) between a supply flow rate and/or a supply time of the organic Ti-containing gas and a supply flow rate and/or a supply time of the halogen-based Ti-containing gas. This will be described in detail hereinafter.

### First Embodiment of the Present Disclosure

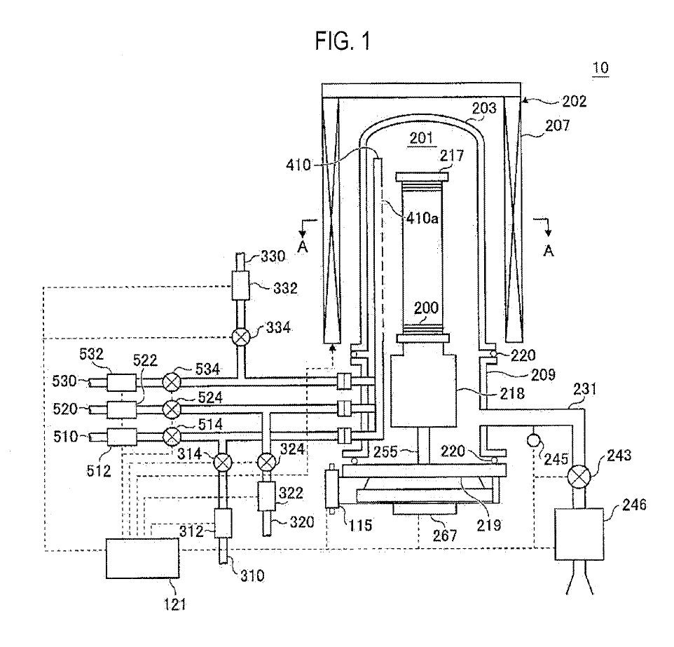

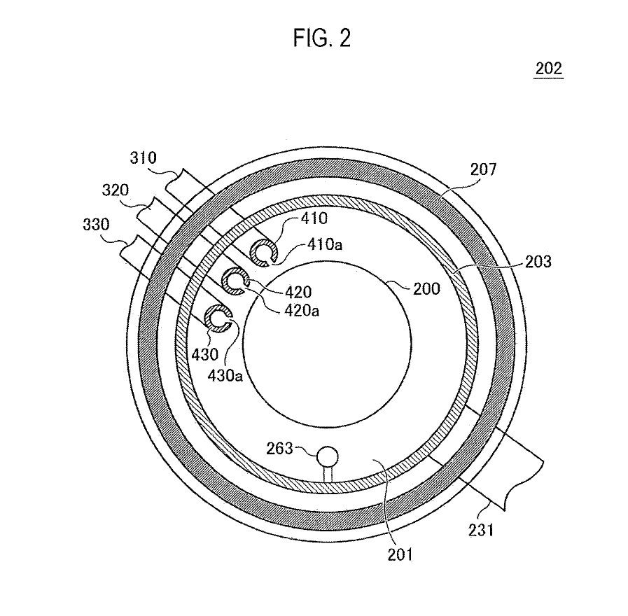

Hereinafter, a first embodiment of the present disclosure will be described with reference to FIGS. 1 to 3. A substrate processing apparatus 10 is configured as one example of an apparatus used in a substrate processing process which is one of the processes of manufacturing a semiconductor device.

### (1) Configuration of Processing Furnace

As shown in FIG. 1, a processing furnace 202 has a heater 207 serving as a heating means (heating mechanism). The heater 207 has a cylindrical shape and is supported by a heater base (not shown) as a support plate so as to be installed vertically.

A reaction tube 203 that forms a reaction vessel (process vessel) in a concentric shape with the heater 207 is disposed inside the heater 207. The reaction tube 203 is formed of a heat resistant material (e.g., quartz (SiO₂), silicon carbide (SiC), or the like), and has a cylindrical shape with a closed top and an open bottom. A process chamber 201 is configured to accommodate wafers 200 as substrates which are horizontally arranged in a boat 217 in vertical multi stages, which will be described later.

Nozzles 410, 420 and 430 are installed in the process chamber 201 to pass through a sidewall of a manifold 209. Gas supply pipes 310, 320, and 330 as gas supply lines are connected to the nozzles 410, 420 and 430, respectively. In this manner, the three nozzles 410, 420 and 430, and the three gas supply pipes 310, 320 and 330 are installed in the reaction tube 203, and plural types of gases, herein, three types of gases (process gases and sources) can be supplied into the process chamber 210.

However, the processing furnace 202 of this embodiment is not limited thereto. For example, a manifold formed of metal is disposed under the reaction tube 203 to support the reaction tube 203, and each nozzle may be installed to pass through the sidewall of the manifold. In this case, an exhaust pipe 231 described later may be further installed in the manifold. Also, in this case, the exhaust pipe 231 may be installed under the reaction tube 203 instead of the manifold. In this manner, a furnace opening of the processing furnace 202 is formed of metal, and a nozzle or the like may be installed in the furnace opening formed of metal.

Mass flow controllers (MFCs) 312, 322, and 332, which are flow rate controllers (flow rate control parts), and valves 314, 324, and 334, which are opening/closing valves, are respectively installed in the gas supply pipes 310, 320, and 330 in this order from an upstream side. Gas supply pipes 510, 520, and 530 for supplying an inert gas are connected to the gas supply pipes 310, 320, and 330 at a downstream side of the valves 314, 324, and 334 thereof, respectively. MFCs 512, 522, and 532, which are flow rate controllers (flow rate control parts), and valves 514, 524, and 534, which are opening/closing valves, are respectively installed in the gas supply pipes 510, 520, and 530 in this order from the upstream side.

Nozzles 410, 420, and 430 are coupled (connected) to front end portions of the gas supply pipes 310, 320, and 330, respectively. The nozzles 410, 420, and 430 are configured as L-shaped long nozzles, and horizontal portions thereof are installed to pass through a sidewall of the manifold 209. Vertical portions of the nozzles 410, 420, and 430 are installed in an annular space formed between the inner wall of the reaction tube 203 and the wafers 200 to extend upward (upward in the stacking direction of the wafers 200) along an inner wall of the reaction tube 203 (that is, extend upward from one end portion of the wafer arrangement region to the other end portion thereof). That is, the nozzles 410, 420, and 430 are installed in a region horizontally surrounding and laterally disposed from the wafer arrangement region in which the wafers 200 are arranged, along the wafer arrangement region.

Gas supply holes 410a, 420a and 430a through which gases are supplied (discharged) are formed in side surfaces of the nozzles 410, 420, and 430, respectively. The gas supply holes 410a, 420a, and 430a are opened toward the center of the reaction tube 203, respectively. A plurality of gas supply holes 410a, 420a, and 430a is formed from a lower portion to an upper portion of the reaction tube 203, and is formed to have the same opening area at the same opening pitch. However, the gas supply holes 410a, 420a, and 430a are not limited thereto. For example, the opening areas of the gas supply holes 410a, 420a, and 430a may be gradually increased along a direction from the lower portion to the upper portion of the reaction tube 203. Thus, the flow rates of gases supplied from the gas supply holes 410a, 420a, and 430a may be uniform.

As described above, in the method of supplying a gas according to this embodiment, the gas is transferred via the nozzles 410, 420, and 430, which are disposed inside a vertically long space of an annular shape defined by the inner wall of the reaction tube 203 and the end portions of the plurality of wafers 200, i.e., a cylindrical space. The gas is firstly discharged into the inside of the reaction tube 203 in the vicinity of the wafers 200 through the opened gas supply holes 410a, 420a and 430a of the nozzles 410, 420 and 430, respectively, and a main flow of the gas in the reaction tube 203 is formed in a direction parallel to surfaces of the wafers 200, i.e., the horizontal direction. With this configuration, the gas can be uniformly supplied to the respective wafers 200, so that an advantageous effect of forming a thin film with uniform thickness on each of the wafers 200 can be provided. Further, a gas having flown above the surfaces of the wafers 200, i.e., a gas remaining after the reaction (residual gas), flows toward an exhaust port, i.e., the exhaust pipe 231 described later. A flow direction of the residual gas is not limited to the vertical direction and may be appropriately specified depending on a position of the exhaust port.

As a process gas, an organic source gas as a first source gas containing a first element (a first metal-containing gas or a first source) is supplied from the gas supply pipe 310 into the process chamber 201 through the MFC 322, the valve 324, and the nozzle 420. As the organic source gas, for example, tetrakisdiethylaminotitanium (Ti[(C₂H₅)₂N]₄, abbreviation: TDEAT) is used as a metal source gas containing Ti, which is a metal element as a first element, and C (C-containing), i.e., an organic metal source gas (an organic metal compound, an organic Ti-containing gas, or an organic Ti source gas) as an organic metal-containing gas. Here, the organic gas as an organic metal source has a meaning broader than that of an amine-based gas, and the amine-based gas is included in the organic gas. For example, cyclopentane (C₅H₁₀) is an organic group but not an amine group. Also, Ti is classified as a transition metal element. When the term “source” is used herein, it may refer to “a liquid source in a liquid state”, “a source gas in a gaseous state”, or both of them.

An inorganic source gas as a second source gas containing a second element (a second source) is supplied from the gas supply pipe 320 into the process chamber 201 through the MFC 312, the valve 314, and the nozzle 410, as a process gas. As the inorganic source gas, for example, titanium tetrachloride (TiCl₄) is used as a metal source gas containing titanium (Ti), which is a metal element as a first element, and not containing carbon (C), i.e., an inorganic metal source gas that is an inorganic metal-containing gas (an inorganic metal compound, an inorganic Ti-containing gas, or an inorganic Ti source gas). The titanium tetrachloride (TiCl₄) is a halogen-based metal-containing gas (also called a metal halogenide, a halogen-based metal source, a halogen-based Ti-containing gas, a halogen-based Ti source gas, or a halogen-based Ti source). Ti is classified as a transition metal element. The halogen-based source is a source containing a halogen group. The halogen group includes a chloro group, a fluoro group, a bromo group, an iodo group, and the like. That is, the halogen group includes a halogen element such as chlorine (Cl), fluorine (F), bromine (Br), or iodine (I).

As a process gas, a nitrogen (N)-containing gas as a reaction gas (reactant), which contains N and reacts with Ti, is supplied from the gas supply pipe 330 into the process chamber 201 through the MFC 332, the valve 334, and the nozzle 430. As the N-containing gas, an N-containing gas that does not contain a metal element, for example, an ammonia (NH₃) gas, may be used.

As an inert gas, for example, a nitrogen (N₂) gas, is supplied from the gas supply pipes 510, 520, and 530 into the process chamber 201 through the MFCs 512, 522, and 532, the valves 514, 524, and 534, and the nozzles 410, 420, and 430, respectively. The inert gas supplied from the gas supply pipes 510, 520, and 530 acts as a purge gas, a dilution gas, or a carrier gas in a substrate processing process described later.

When TiCl₄ or TDEAT which is a compound remaining in a liquid state at room temperature under normal pressure is used as a process gas, the TiCl₄ or TDEAT in a liquid state is vaporized by a vaporization system such as a vaporizer or a bubbler and supplied into the process chamber 201 as the TiCl₄ or TDEAT gas.

A process gas supply system is mainly configured by the gas supply pipes 310, 320 and 330, the MFCs 312, 322 and 332, and the valves 314, 324 and 334. It may be considered that the nozzles 410, 420 and 430 are included in the process gas supply system. The process gas supply system may be simply called a gas supply system.

When the metal-containing gas as a source gas described above is supplied from the gas supply pipes 310 and 320, a metal-containing gas supply system as a source gas supply system is mainly configured by the gas supply pipes 310 and 320, the MFCs 312 and 322, and the valves 314 and 324. It may also be considered that the nozzles 410 and 420 are included in the source gas supply system. The source gas supply system may be called a source supply system.

When an organic source gas is supplied as a source gas from the gas supply pipe 310, an organic source gas supply system is mainly configured by the gas supply pipe 310, the MFC 312, and the valve 314. It may be considered that the nozzle 410 is included in the organic source gas supply system. The organic source gas supply system may be called an organic source supply system. When an organic metal source gas as an organic metal-containing gas is supplied from the gas supply pipe 310, the organic source gas supply system may be called an organic metal source gas supply system (an organic metal source supply system) as an organic metal-containing gas supply system. When a TDEAT gas is supplied from the gas supply pipe 310, the organic metal source gas supply system may be called a TDEAT gas supply system. The TDEAT gas supply system may be called a TDEAT supply system.

When an inorganic source gas is supplied as a source gas from the gas supply pipe 320, an inorganic source gas supply system is mainly configured by the gas supply pipe 320, the MFC 322, and the valve 324. It may be considered that the nozzle 420 is included in the inorganic source gas supply system. The inorganic source gas supply system may be called an inorganic source supply system. When an inorganic metal source gas as an inorganic metal-containing gas is supplied from the gas supply pipe 320, the inorganic source gas supply system may be called an inorganic metal source gas supply system (an inorganic metal source supply system) as an inorganic metal-containing gas supply system. When a halogen-based source gas is supplied from the gas supply pipe 320, the inorganic source gas supply system may be called a halogen-based source gas supply system. The halogen-based source gas supply system may be called a halogen-based source supply system. When a TiCl₄ gas is supplied from the gas supply pipe 320, the halogen-based source gas supply system may be called a TiCl₄ gas supply system. The TiCl₄ gas supply system may be called a TiCl₄ supply system.

When a reaction gas is supplied from the gas supply pipe 330, a reaction gas supply system is mainly configured by the gas supply pipe 330, the MFC 332, and the valve 334. It may be considered that the nozzle 430 is included in the reaction gas supply system. When an N-containing gas is supplied from the gas supply pipe 330, the reaction gas supply system may be called an N-containing gas supply system. When an NH₃ gas is supplied from the gas supply pipe 330, the N-containing gas supply system may be called an NH₃ gas supply system. The NH₃ gas supply system may be called an NH₃ supply system.

Further, an inert gas supply system is mainly configured by the gas supply pipes 510, 520, and 530, the MFCs 512, 522, and 532, and the valves 514, 524, and 534. When an inert gas is supplied as a carrier gas, the inert gas supply system may be called a carrier gas supply system. The inert gas supply system may be called a purge gas supply system, in that the inert gas also acts as a purge gas.

An exhaust pipe 231 through which an internal atmosphere of the process chamber 201 is exhausted is installed in the reaction tube 203. A vacuum pump 246 serving as a vacuum exhaust device is connected to the exhaust pipe 231 through a pressure sensor 245 serving as a pressure detector (pressure detecting part) for detecting an internal pressure of the process chamber 201, an auto pressure controller (APC) valve 244 serving as a pressure controller (pressure control part). When operating the vacuum pump 246, the APC valve 244 may be open or closed to vacuum-exhaust the internal atmosphere of the process chamber 201 or stop the vacuum-exhausting, respectively, and, in a state where the vacuum pump 246 is operated, the internal pressure of the process chamber 201 may be adjusted by adjusting a degree of the valve opening of the APC valve 244 based on pressure information detected by the pressure sensor 245. An exhaust system is mainly configured by the exhaust pipe 231, the APC valve 244, and the pressure sensor 245. Also, it may be considered that the vacuum pump 246 is included in the exhaust system.

A seal cap 219, which functions as a furnace port cover configured to hermetically seal a lower end opening of the reaction tube 203, is installed under the reaction tube 203. The seal cap 219 is configured to contact the lower end of the reaction tube 203 from the below in the vertical direction. The seal cap 219 may be formed of metal such as, for example, steel use stainless (SUS), and have a disc shape. An O-ring 220, which is a seal member in contact with the lower end of the reaction tube 203, is installed at an upper surface of the seal cap 219. A rotation mechanism 267 configured to rotate the boat 217, which will be described later, is installed at a side of the seal cap 219 opposite to the process chamber 201. A rotation shaft 255 of the rotation mechanism 267 passes through the seal cap 219 and is connected to the boat 217. The rotation mechanism 267 is configured to rotate the wafers 200 by rotating the boat 217. The seal cap 219 is configured to be vertically moved by a boat elevator 115, which is an elevation mechanism vertically disposed at the outside of the reaction tube 203. The boat elevator 115 is configured to load and unload the boat 217 into and from the process chamber 201 by elevating or lowering the seal cap 219. That is, the boat elevator 115 is configured as a transfer device (transfer mechanism) that transfers the boat 217, i.e., the wafers 200, into and out of the process chamber 201.

The boat 217, which is used as a substrate support, is configured to support a plurality of wafers 200, e.g., 25 to 200 sheets, in such a manner that the wafers 200 are horizontally stacked in a vertical direction and in multiple stages, i.e., being separated from each other, with the centers of the wafers 200 aligned with each other. The boat 217 is made of a heat-resistant material such as, e.g., quartz or silicon carbide (SiC). A lower portion of the boat 217 is supported by heat insulating plates 218, which are formed of a heat resistant material such as, for example, quartz or SiC and which are stacked in a horizontal posture and a multi-stage manner. This configuration prevents a heat transfer from the heater 207 to the seal cap 219. However, this embodiment is not limited thereto. Instead of installing the heat insulating plates 218 at the lower portion of the boat 217, for example, a heat insulating tube formed of a tubular member, which is formed of a heat resistant material such as quartz or SiC, may be installed.

A temperature sensor 263 serving as a temperature detector is installed in the reaction tube 203, and an amount of electric current to be applied to the heater 207 is adjusted based on temperature information detected by the temperature sensor 263, so that the interior of the process chamber 201 has a desired temperature distribution. The temperature sensor 263 is configured in an L shape, like the nozzles 410, 420, and 430, and is installed along the inner wall of the reaction tube 203.

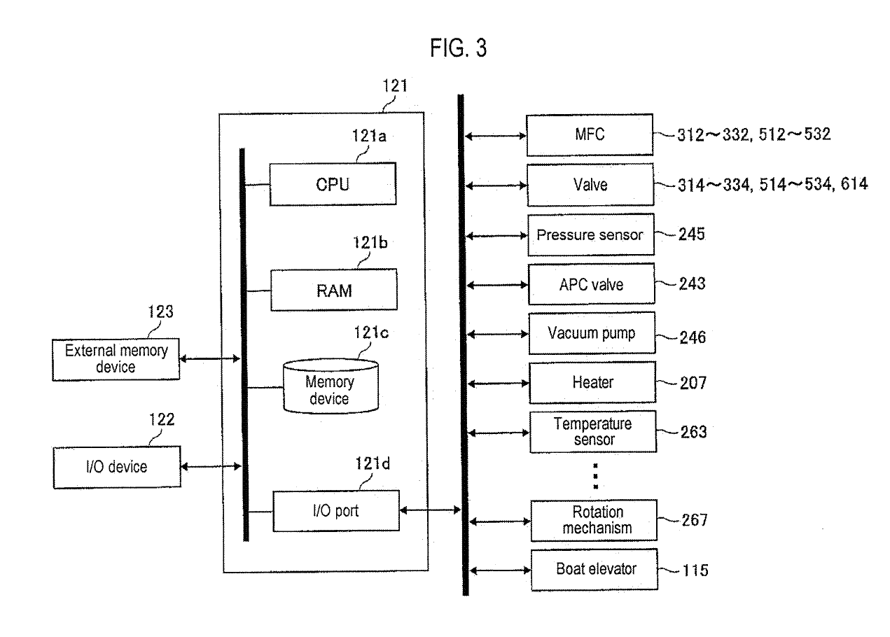

As illustrated in FIG. 3, a controller 121 serving as a control part (control means) is configured by a computer including a central processing unit (CPU) 121a, a random access memory (RAM) 121b, a memory device 121c, and an I/O port 121d. The RAM 121b, the memory device 121c, and the I/O port 121d are configured to exchange data with the CPU 121a via an internal bus 121e. An input/output device 122 configured by, for example, a touch panel or the like is connected to the controller 121.

The memory device 121c is configured by, for example, a flash memory, a hard disc drive (HDD), or the like. A control program for controlling operations of the substrate processing apparatus, a process recipe in which a sequence, condition, or the like for the substrate processing to be described later is written, and the like are readably stored in the memory device 121c. The process recipe, which is a combination of sequences, causes the controller 121 to execute each sequence in a substrate processing process to be described later in order to obtain a predetermined result, and functions as a program. Hereinafter, the process recipe, the control program, and the like may be generally referred to simply as a program. When the term “program” is used in the present disclosure, it should be understood as including the process recipe, the control program, or a combination of the process recipe and the control program. Further, the RAM 121b is configured as a memory area (work area) in which a program, data, or the like read by the CPU 121a is temporarily stored.

The I/O port 121d is connected to the above-described MFCs 312, 322, 332, 512, 522 and 532, the valves 314, 324, 334, 514, 524 and 534, the APC valve 243, the pressure sensor 245, the vacuum pump 246, the heater 207, the temperature sensor 263, the rotation mechanism 267, the boat elevator 115, and the like.

The CPU 121a is configured to read and execute the control program from the memory device 121c, and also to read the process recipe from the memory device 121c according to an operation command input from the input/output device 122, or the like. The CPU 121a is configured to control the flow rate adjusting operation of various types of gases by the MFCs 312, 322, 332, 512, 522, and 532, the opening/closing operation of the valves 314, 324, 334, 514, 524 and 534, the pressure adjusting operation based on an opening/closing operation of the APC valve 243 and the pressure sensor 245 by the APC valve 243, the temperature adjusting operation of the heater 207 based on the temperature sensor 263, the driving and stopping of the vacuum pump 246, the rotation of the boat 217 and the rotation speed adjusting operation of the boat 217 by the rotation mechanism 267, the elevation operation of the boat 217 by the boat elevator 115, and the like, according to the read process recipe.

The controller 121 may be configured by installing the above-described program, which is stored in an external memory device 123 (e.g., a magnetic tape, a magnetic disc such as a flexible disc or a hard disc, an optical disc such as a compact disc (CD) or a digital versatile disc (DVD), a magneto-optical (MO) disc, a semiconductor memory such as a universal serial bus (USB) memory or a memory card, etc.), on the computer. The memory device 121c or the external memory device 123 is configured as a non-transitory computer-readable recording medium. Hereinafter, they will be generally referred to simply as “a recording medium”. When the term “recording medium” is used in the present disclosure, it may be understood as including the memory device 121c, the external memory device 123, or both of the memory device 121c and the external memory device 123. Further, the program may be supplied from the computer using a communication means such as the Internet or a dedicated line, rather than through the external memory device 123.

### (2) Substrate Processing Process (Film Forming Process)

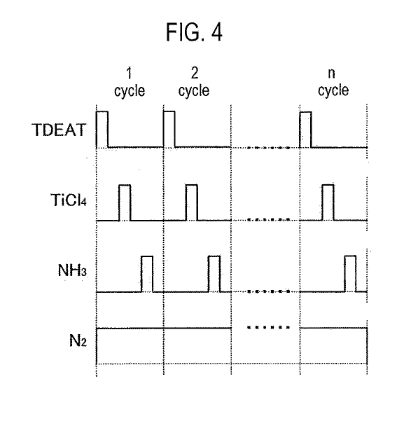

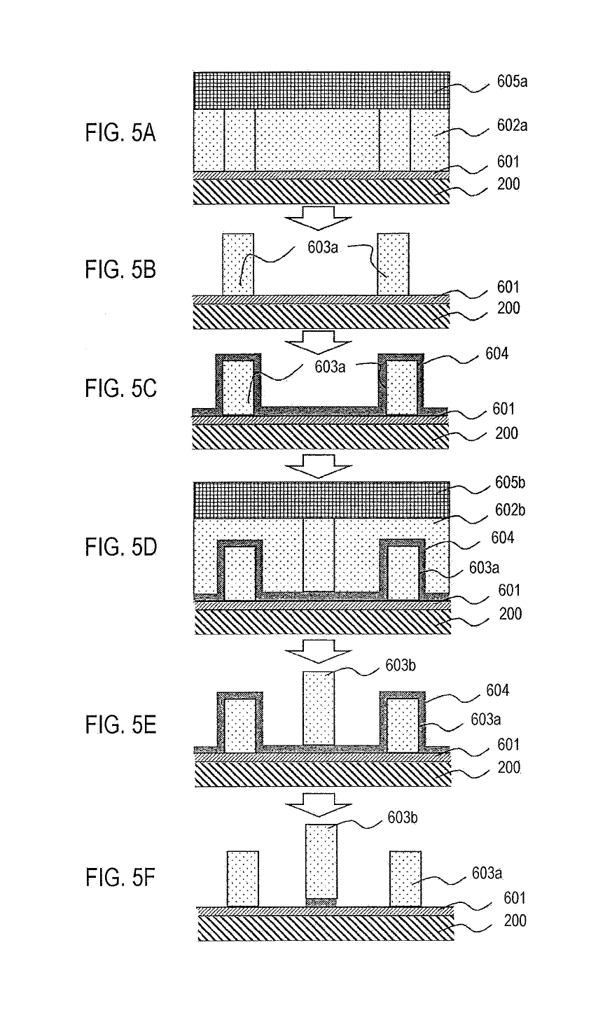

An example of a process of forming a metal film constituting, for example, a metal hard mask, on a substrate, which is one of the processes of manufacturing a semiconductor device, will be described with reference to FIGS. 4 and 5. The process of forming a metal film is performed using the processing furnace 202 of the above-described substrate processing apparatus 10. In the following description, the operations of respective parts constituting the substrate processing apparatus 10 are controlled by the controller 121.

### First Embodiment of the Present Disclosure

A film forming sequence (also simply referred to as a “sequence”) preferred in this embodiment includes a process of forming a metal-containing film containing a first element and a second element by performing a predetermined number of times in a time-division manner (asynchronously, intermittently, or in a pulse manner) a cycle including a process of supplying an organic metal source gas (e.g., a TDEAT gas) containing a first element (e.g., titanium (Ti)) as a metal element to the wafers 200, a process of supplying a halogen-based metal source gas (e.g., a TiCl₄ gas) containing the first element to the wafers 200, and a process of supplying a reaction gas (e.g., an NH₃ gas) containing a second element (e.g., nitrogen (N)) and reacting with the first element to the wafers 200, wherein a value of film stress of the metal-containing film is controlled by controlling at least one value of a supply flow rate and a supply time of the organic metal source gas in the act of supplying an organic metal source gas.

In the present disclosure, the expression “performing processing (also referred to as a process, a cycle, a step or the like) a predetermined number of times” means performing the processing or the like once or plural times. That is, it means performing the processing one or more times. FIG. 4 illustrates an example of repeating each processing (cycle) by n cycles. A value of n is appropriately selected depending on a film thicknesses required for a TiN film to be finally formed. That is, the number of performing each processing described above is determined according to a target film thickness.

Further, when the term “wafer” is used in the present disclosure, it should be understood as either a “wafer per se,” or “the wafer and a laminated body (aggregate) of certain layers or films formed on a surface of the wafer” (that is, the wafer and certain layers or films formed on the surface of the wafer is collectively referred to as a wafer). Also, when the term “surface of a wafer” is used in the present disclosure, it should be understood as either a “surface (exposed surface) of a wafer per se,” or a “surface of a certain layer or film formed on the wafer, i.e., an outermost surface of the wafer as a laminated body”.

Thus, in the present disclosure, the expression “a specified gas is supplied to a wafer” may mean that “the specified gas is directly supplied to a surface (exposed surface) of a wafer per se,” or that “the specified gas is supplied to a surface of a certain layer or film formed on the wafer, i.e., to an outermost surface of the wafer as a laminated body”. Also, in the present disclosure, the expression “a certain layer (or film) is formed on a wafer” may mean that “the certain layer (or film) is directly formed on the surface (exposed surface) of the wafer per se,” or that “the certain layer (or film) is formed on the surface of a certain layer or film formed on the wafer, i.e., on an outermost surface of the wafer as a laminated body”.

Also, in the present disclosure, the term “substrate” is interchangeably used with the term “wafer”. Thus, in the above description, the term “wafer” may be replaced with the term “substrate”.

Further, in the present disclosure, the term “metal film” refers to a film formed of a conductive material containing a metal element, and the metal film includes a conductive metal nitride film, a conductive metal oxide film, a conductive metal oxynitride film, a conductive metal composite film, a conductive metal alloy film, a conductive metal silicide film, a conductive metal carbide film, a conductive metal carbonitride film, and the like. Also, the TiN film is a conductive metal nitride film, the TiC film is a conductive metal carbide film, and the TiCN film is a conductive metal carbonitride film.

### (Wafer Charging and Boat Loading)

When a plurality of wafers 200 is charged on the boat 217 (wafer charging), as illustrated in FIG. 1, the boat 217 supporting the plurality of wafers 200 is lifted up by the boat elevator 115 to be loaded into the process chamber 201 (boat loading). In this state, the seal cap 219 seals the lower end opening of the manifold 209 via the O-ring 220.

### (Pressure Adjustment and Temperature Adjustment)

The interior of the process chamber 201, i.e., a space where the wafers 200 are present, is vacuum-exhausted by the vacuum pump 246 to a desired pressure (degree of vacuum). At this time, the internal pressure of the process chamber 201 is measured by the pressure sensor 245, and the APC valve 243 is feedback-controlled based on the measured pressure information (pressure adjustment). The vacuum pump 246 is always kept in an operative state at least until the processing on the wafers 200 is completed. Further, the wafers 200 within the process chamber 201 are heated by the heater 207 to a desired temperature. At this time, an amount of electric current supplied to the heater 207 is feedback-controlled based on the temperature information detected by the temperature sensor 263 so that a desired temperature distribution is formed in the interior of the process chamber 201 (temperature adjustment). The heating of the interior of the process chamber 201 by the heater 207 is continuously performed at least until the processing on the wafers 200 is completed. Subsequently, the rotation of the boat 217 and wafers 200 by the rotation mechanism 267 begins. The rotation of the boat 217 and wafers 200 by the rotation mechanism 267 is continuously performed at least until the processing on the wafers 200 is completed.

### (TiN Film Forming Step)

Subsequently, a step of forming a TiN film is performed. The TiN film forming step includes a step of supplying an organic source gas, a step of removing a residual gas, a step of supplying a halogen-based source gas, a step of removing a residual gas, a step of supplying an N-containing gas, and a step of removing a residual gas, which will be described below.

### (Step of Supplying Organic Source Gas)

The valve 314 is opened and a TDEAT gas as an organic source gas is supplied into the gas supply pipe 310. A flow rate of the TDEAT gas flowing inside the gas supply pipe 310 is adjusted by the MFC 312. The flow rate-adjusted TDEAT gas is supplied into the process chamber 201 from the gas supply hole 410a of the nozzle 410 and exhausted via the exhaust pipe 231. At this time, the TDEAT gas is supplied to the wafers 200. That is, a surface of the wafer 200 is exposed to the TDEAT gas. At this time, the valve 514 is simultaneously opened, and an N₂ gas is supplied into the gas supply pipe 510. A flow rate of the N₂ gas flowing inside the gas supply pipe 510 is adjusted by the MFC 512. The flow rate-adjusted N₂ gas is supplied into the process chamber 201 together with the TDEAT gas and exhausted via the exhaust pipe 231. Also, at this time, in order to prevent the TDEAT gas from flowing into the nozzles 420 and 430, the valves 524 and 534 are opened and the N₂ gas is supplied into the gas supply pipes 520 and 530. The N₂ gas is supplied into the process chamber 201 through the gas supply pipes 320 and 330 and the nozzles 420 and 430, and exhausted via the exhaust pipe 231.

At this time, the APC valve 243 is appropriately adjusted to set an internal pressure of the process chamber 201 to (predetermined) pressure within a range of, for example, 1 to 10000 Pa, preferably, to (predetermined) pressure within a range of 1 to 500 Pa, and more preferably, to (predetermined) pressure within a range of 40 to 60 Pa. When pressure is higher than 10000 Pa, a residual gas described later may not be sufficiently removed, and when pressure is lower than 1 Pa, there is a possibility that a reaction rate of the TDEAT gas is not sufficiently obtained. Further, in the present disclosure, when a numerical value range is described as, e.g., 1 to 10000 Pa, it means 1 Pa or higher and 10000 Pa or lower. That is, 1 Pa and 10000 Pa are included within the numerical value range. This is the same for all the numerical values described in the present disclosure, such as a flow rate, a time, a temperature, and the like, as well as pressure.

A supply flow rate of the TDEAT gas controlled by the MFC 312 is set to a (predetermined) flow rate within a range of, for example, 1 to 10000 sccm, preferably, to a (predetermined) flow rate within a range of 1 to 1000 sccm, and more preferably, to a (predetermined) flow rate within a range of 1 to 200 sccm. Under the condition of the internal pressure of the process chamber 201 described above and the temperature of the heater 207 described later, the saturated adsorption of the TDEAT gas onto the wafers 200 does not occur in many cases, and thus, as a supply flow rate of the TDEAT gas is increased, a thickness of a first Ti-containing layer deposited on the wafers 200, which will be described later, can be increased, compared with a case having the same supply time of the TDEAT gas. That is, it is possible to increase a reaction rate (film formation rate) of the TDEAT gas. However, when a flow rate is higher than 10000 sccm, a residual gas described later may not be sufficiently removed. Further, when the flow rate is lower than 1 sccm, there is a possibility that the reaction rate of the TDEAT gas is not sufficiently obtained.

A supply flow rate of the N₂ gas controlled by each of the MFCs 512, 522, and 532 is set to a (predetermined) flow rate within a range of, for example, 10 to 20000 sccm, preferably, to a (predetermined) flow rate within a range of 400 to 15000 sccm, and more preferably, to a (predetermined) flow rate within a range of 300 to 600 sccm. If the flow rate is higher than 20000 sccm, there is a possibility that the reaction rate of the TDEAT gas is not sufficiently obtained, and if the flow rate is lower than 10 sccm, a residual gas described later may not be sufficiently removed.

A time duration for which the TDEAT gas is supplied to the wafers 200, i.e., a gas supply time (irradiation time), is set to a (predetermined) time within a range of, for example, 0.1 to 120 seconds, preferably, a (predetermined) time within a range of 0.5 to 30 seconds, and more preferably, to a (predetermined) time within a range of 8 to 12 seconds. Under the condition of the internal pressure of the process chamber 201 described above and the temperature of the heater 207 described later, the saturated adsorption of the TDEAT gas onto the wafer 200 does not occur in many cases, and thus, as a supply flow rate of the TDEAT gas is increased, a thickness of the first Ti-containing layer deposited on the wafers 200, which will be described later, can be increased, compared with a case having the same supply flow rate of the TDEAT gas. That is, it is possible to increase a reaction rate (film formation rate) of the TDEAT gas. However, when a supply time is longer than 60 seconds, there is a possibility that C, N or the like is introduced more than a permissible amount. Further, when the supply time is shorter than 0.1 seconds, there is a possibility that the reaction rate is lowered.

A temperature of the heater 207 is set such that a temperature of the wafers 200 becomes a (predetermined) temperature within a range of, for example, 200 to 600 degrees C., preferably, to a (predetermined) temperature within a range of 200 to 550 degrees C., and more preferably, to a (predetermined) temperature within a range of 200 to 400 degrees C. At a temperature of 600 degrees C. or higher, the TDEAT gas may be promoted to be thermally decomposed, thereby causing degradations of controllability of a film thickness and uniformity due to a significantly increased film formation rate and causing increased resistivity due to introduction of a large amount of impurities. On the other hand, at a temperature lower than 200 degrees C., reactivity is lowered so as to make it difficult to form a film. Gases flowing into the process chamber 201 include only the TDEAT gas and the N₂ gas. Due to the supply of the TDEAT gas, the first Ti-containing layer is formed on the wafers 200 (on the base film of the surface).

The first Ti-containing layer may be a Ti layer including only a single Ti atom, or may include other elements resulting from each source. In the organic source gas supply step using the TDEAT gas, C, N, or H may be included. Thus, the first Ti-containing layer includes a TDEAT layer that is a deposit layer of TDEAT. The TDEAT layer includes a deposit layer formed of TDEAT molecules. The TDEAT molecules forming the TDEAT layer also include Ti partially disconnected with C, N, or H.

Under the conditions of the internal pressure of the process chamber 201 and the temperature of the heater 207 described above, the saturated adsorption of the TDEAT molecules onto the wafers 200 does not occur in many cases, and thus, even when the internal pressure of the process chamber and the temperature of the heater at the time of supplying the TDEAT gas are set to be the same, it is possible to control (adjust, modulate, tune, and control) a film thickness of the first Ti-containing layer deposited on the wafers 200 by changing (adjusting and controlling) a supply flow rate and a supply time of the TDEAT gas. That is, by changing (adjusting and controlling) the supply flow rate and the supply time of the TDEAT gas, it is possible to control (adjust, modulate, tune, and control) a film formation rate of the first Ti-containing layer deposited on the wafers 200.

When a supply flow rate of the TDEAT gas is small or when a supply time of the TDEAT gas is shortened, a first Ti-containing layer having a thickness less than one molecular layer is formed on the wafers 200. When a primary component of the first Ti-containing layer is only a single Ti atom, the first Ti-containing layer may be said to have a thickness less than one atomic layer. As the supply flow rate of the TDEAT gas is increased or as the supply time of the TDEAT gas is lengthened, a thickness of the first Ti-containing layer formed on the wafers 200 has a thickness ranging from a one molecular layer to several molecular layers. When a primary component of the first Ti-containing layer is only the single Ti atom, the first Ti-containing layer may be said to have a thickness ranging from one atomic layer to several atomic layers. Here, a layer having a thickness less than one molecular layer refers to a discontinuously formed molecular layer, and a layer having a thickness equal to one molecular layer refers to a continuously formed molecular layer. A layer having a thickness less than one atomic layer refers to a discontinuously formed atomic layer, and a layer having a thickness equal to one atomic layer means a continuously formed atomic layer. This is also the same for the following example.

### (Residual Gas Removing Step)

Thereafter, the valve 314 is closed to stop the supply of the TDEAT gas. At this time, while the APC valve 243 of the exhaust pipe 231 is opened, the interior of the process chamber 201 is vacuum-exhausted by the vacuum pump 246 to remove from the process chamber 201 the TDEAT gas remaining in the process chamber 201, which has not reacted or remains after having contributed to the formation of the first Ti-containing layer. Also, at this time, the valves 514, 524 and 534 are opened so that the supply of the N₂ gas into the process chamber 201 is maintained. The N₂ gas acts as a purge gas to thereby increase an effect of removing from the process chamber 201 the TDEAT gas remaining in the process chamber 201, which has not reacted or remains after having contributed to the formation of the first Ti-containing layer.

At this time, the gas remaining in the process chamber 201 may not be completely removed, and the interior of the process chamber 201 may not be completely purged. When the amount of the gas remaining in the process chamber 201 is very small, it may not adversely affect the subsequent step. A flow rate of the N₂ gas supplied into the process chamber 201 also need not be high. For example, by supplying the approximately same amount of the N₂ gas as the volume of the reaction tube 203 (the process chamber 201), the purging process can be performed without adversely affecting the subsequent step. As described above, since the interior of the process chamber 201 is not completely purged, the purge time can be reduced which can improve the throughput. In addition, the consumption of the N₂ gas can also be restricted to a required minimal amount.

### (Step of Supplying Halogen-Based Source Gas)

Subsequently, the valve 324 is opened and a TiCl₄ gas as a halogen-based source is supplied into the gas supply pipe 320. A flow rate of the TiCl₄ gas flowing inside the gas supply pipe 320 is adjusted by the MFC 322. The flow rate-adjusted TiCl₄ gas is supplied into the process chamber 201 from the gas supply hole 420a of the nozzle 420 and is exhausted via the exhaust pipe 231. At this time, the TiCl₄ gas is supplied to the wafers 200. That is, a surface of the wafer 200 is exposed to the TiCl₄ gas. At this time, the valve 524 is simultaneously opened and the inert gas such as the N₂ gas is supplied into the gas supply pipe 520. The N₂ gas flowing inside the gas supply pipe 520 is adjusted in a flow rate by the MFC 522. The flow rate-adjusted N₂ gas is supplied into the process chamber 201 together with the TiCl₄ gas and is exhausted via the exhaust pipe 231. Also, at this time, in order to prevent the TiCl₄ gas from flowing into the nozzles 410 and 430, the valves 514 and 534 are opened and the N₂ gas is supplied into the gas supply pipes 510 and 530. The N₂ gas is supplied into the process chamber 201 through the gas supply pipes 310 and 330 and the nozzles 410 and 430, and exhausted via the exhaust pipe 231.

At this time, the APC valve 243 is appropriately adjusted to set the internal pressure of the process chamber 201 to be (predetermined) pressure within a range of, for example, 1 to 70000 Pa, preferably, to (predetermined) pressure within a range of 1 to 1333 Pa, and more preferably, to (predetermined) pressure within a range of 20 to 50 Pa. When the pressure is higher than 70000 Pa, a residual gas described later may not be sufficiently removed, and when the pressure is lower than 0.01 Pa, there is a possibility that a reaction rate of the TiCl₄ gas is not sufficiently obtained.

A supply flow rate of the TiCl₄ gas controlled by the MFC 322 is set to a (predetermined) flow rate within a range of, for example, 1 to 10000 sccm, preferably, to a (predetermined) flow rate within a range of 10 to 2000 sccm, and more preferably, to a (predetermined) flow rate within a range of 10 to 600 sccm. When a flow rate is higher than 10000 sccm, a residual gas described later may not be sufficiently removed, and when the flow rate is lower than 1 sccm, there is a possibility that the reaction rate of the TiCl₄ gas is not sufficiently obtained.

A supply flow rate of the N₂ gas controlled by each of the MFCs 512, 522, and 532 is set to a (predetermined) flow rate within a range of, for example, 1 to 20000 sccm, preferably, to a (predetermined) flow rate within a range of 500 to 15000 sccm, and more preferably, to a (predetermined) flow rate within a range of 600 to 800 sccm. When the flow rate is higher than 20000 sccm, there is a possibility that the reaction rate of the TiCl₄ gas is not sufficiently obtained, and when the flow rate is lower than 1 sccm, a residual gas described later may not be sufficiently removed.

A time duration for which the TiCl₄ gas is supplied to the wafers 200, i.e., a gas supply time (irradiation time), is set to a (predetermined) time within a range of for example, 0.1 to 120 seconds, preferably, to a (predetermined) time within a range of 1 to 30 seconds, and more preferably, to a (predetermined) time within a range of 2 to 6 seconds. When a supply time is longer than 120 seconds, there is a possibility that a large amount of Cl or the like is introduced, and when the supply time is shorter than 0.1 seconds, there is a possibility that a film formation rate is lowered.

The temperature of the heater 207 is set to be the same as that in the organic source gas supply step. Gases flowing into the process chamber 201 are only the TiCl₄ gas and the N₂ gas, and the TiCl₄ gas reacts with at least a portion of the first Ti-containing layer formed on the wafers 200 by the supply of the TiCl₄ gas supply to form a second Ti-containing layer on the wafers 200 (the first Ti-containing layer).

Like the first Ti-containing layer formed in the organic source gas supply step, a second Ti-containing layer formed in a halogen-based source gas supply step may also be a Ti layer including only a single Ti atom, but it may also include other atoms resulting from each source, and, in the halogen-based source gas supply step, the second Ti-containing layer may include Cl that is a halogen-based element in many cases. That is, the second Ti-containing layer includes a TiCl₄ layer as an adsorption layer of TiCl₄. The TiCl₄ layer includes, in addition to a continuous absorption layer formed of TiCl₄ molecules, a discontinuous adsorption layer as well. That is, the TiCl₄ layer includes an adsorption layer having a thickness of one molecular layer or less, which is formed of TiCl₄ molecules. The TiCl₄ molecules forming the TiCl₄ layer also include a molecule in which a bond of Ti and Cl is partially broken. At the internal pressure of the process chamber 201 and at the temperature of the heater 207 described above, the saturated adsorption of the TiCl₄ gas onto the wafers 200 occurs in many cases.

### (Residual Gas Removing Step)

After the second Ti-containing layer is formed, the valve 324 is closed to stop the supply of the TiCl₄ gas. Further, through the same process sequence as the residual gas removing step after the organic source gas supply step, the TiCl₄ gas remaining in the process chamber 201, i.e., a space where the wafers 200 in which the second Ti-containing layer is formed exist, which has not reacted or remains after having contributed to the formation of the second Ti-containing layer, is removed from the process chamber 201. At this time, the fact that gases remaining in the process chamber may not be completely removed is also applicable to the residual gas removing step after the organic source gas supply step.

### (Step of Supplying N-Containing Gas)

After the residual gas within the process chamber 201 is removed, the valve 334 is opened and an NH₃ gas as an N-containing gas is supplied into the gas supply pipe 330. A flow rate of the NH₃ gas flowing inside the gas supply pipe 330 is adjusted by the MFC 332. The flow rate-adjusted NH₃ gas is supplied into the process chamber 201 from the gas supply hole 430a of the nozzle 430 and exhausted via the exhaust pipe 231. The NH₃ gas supplied into the process chamber 201 is activated by heat and then is exhausted via the exhaust pipe 231. At this time, the NH₃ gas activated by heat is supplied to the wafers 200. That is, a surface of the wafer 200 is exposed to the NH₃ gas activated by heat. At this time, the valve 534 is simultaneously opened and the N₂ gas is supplied into the gas supply pipe 530. The N₂ gas flowing inside the gas supply pipe 530 is adjusted in a flow rate by the MFC 532. The N₂ gas is supplied into the process chamber 201 together with the NH₃ gas and is exhausted via the exhaust pipe 231. At this time, in order to prevent the NH₃ gas from flowing into the nozzles 410 and 420, the valves 514 and 524 are opened and the N₂ gas is supplied into the gas supply pipes 510 and 520. The N₂ gas is supplied into the process chamber 201 through the gas supply pipes 310 and 320 and the nozzles 410 and 420, and exhausted via the exhaust pipe 231.

When the NH₃ gas is supplied, the APC valve 243 is appropriately adjusted to set the internal pressure of the process chamber 201 to be (predetermined) pressure within a range of, for example, 0.01 to 70000 Pa, preferably, to (predetermined) pressure within a range of 1 to 1330 Pa, and more preferably, to (predetermined) pressure within a range of 50 to 100 Pa. When the pressure is higher than 70000 Pa, a residual gas described later may not be sufficiently removed, and when the pressure is lower than 0.01 Pa, there is a possibility that a sufficient film formation rate is not obtained.

A supply flow rate of the NH₃ gas controlled by the MFC 332 is set to a (predetermined) flow rate within a range of, for example, 10 to 50000 sccm, preferably, to a (predetermined) flow rate within a range of 300 to 10000 sccm, and more preferably, to a (predetermined) flow rate within a range of 1000 to 8000 sccm. A higher flow rate is preferable since the introduction of impurities, which result from a source gas, into a TiN film can be reduced as the flow rate becomes higher. However, when the flow rate is higher than 50000 sccm, a residual gas in a residual gas removing step described later may not be sufficiently removed. When the flow rate is lower than 0.1 slm, there is a possibility that a sufficient reaction does not occur.

A supply flow rate of the N₂ gas controlled by each of the MFCs 512, 522, and 532 is set to a (predetermined) flow rate within a range of, for example, 10 to 20000 sccm, preferably, to a (predetermined) flow rate within a range of 400 to 15000 sccm, and more preferably, to a (predetermined) flow rate within a range of 400 to 7500 sccm. When the flow rate is higher than 20000 sccm, there is a possibility that the film formation rate becomes too lower, and when the flow rate is lower than 10 sccm, there is a possibility that the NH₃ gas is not sufficiently supplied to the wafers 200.

A time duration for which the NH₃ gas is supplied to the wafers 200, i.e., a gas supply time (irradiation time), is set to a (predetermined) time within a range of, for example, 0.001 to 300 seconds, preferably, to a (predetermined) time within a range of 0.1 to 60 seconds, and more preferably, to a (predetermined) time within a range of 10 to 25 seconds. A lengthened supply time is preferable since the introduction of impurities, which result from a source gas, into a TiN film can be reduced as the supply time is longer. However, when the supply time is longer than 300 seconds, there is a possibility that throughput degrades. When the supply time is shorter than 0.001 seconds, there is a possibility that it is not sufficiently reacted with the TiCl₄ gas.

The temperature of the heater 207 is set to be the same temperature as that in the organic source gas supply step and the halogen-based source gas supply step.

At this time, gases flowing into the process chamber 201 are only the NH₃ gas and the N₂ gas. A substitution reaction occurs between the NH₃ gas and at least a portion of the first Ti-containing layer and the second Ti-containing layer formed on the wafers 200 in the halogen-based source gas supply step. Through the substitution reaction, a TiN layer including Ti and N is formed on the wafers 200. The TiN layer may include other elements C, N, H, or Cl resulting from each source included in the second Ti-containing layer and the first Ti-containing layer in which the substitution reaction did not occur. Thus, primary components of the TiN layer are Ti and N, but since the TiN layer may include other atoms resulting from each source, the TiN layer may also be called a TiN layer, a TiC layer, a TiCN layer, or the like.

### (Residual Gas Removing Step)

After the TiN layer is formed, the valve 334 is closed to stop the supply of the NH₃ gas. Further, through the same process sequence as that in the residual gas removing step after the organic source gas supply step, the non-reacted NH₃, the reaction byproducts, the NH₃ that has contributed to the formation of the TiN layer, and the like, all which remain in the process chamber 201, i.e., in a space where the wafers 200 in which the TiN layer is formed exist, are removed from the process chamber 201. At this time, the fact that gases remaining in the process chamber may not be completely removed is also applicable to the residual gas removing step after the organic source gas supply step.

### (Performing Predetermined Number of Times)

A cycle in which the organic source gas supply step, the residual gas removing step, the halogen-based source gas supply step, the residual gas removing step, the N-containing gas supply step, and the residual gas supply step described above are sequentially performed in a time-division manner is performed once or more times (predetermined number of times), that is, the process of the organic source gas supply step, the residual gas removing step, the halogen-based source gas supply step, the residual gas removing step, the N-containing gas supply step, and the residual gas supply step are set as one cycle, and the processes are executed by n cycles (where n is an integer equal to or greater than 1) to form a TiN film as a metal composite film having a predetermined thickness (for example, 0.1 to 10 nm) on the wafers 200. Preferably, the foregoing cycle is repeatedly performed plural times.

When the cycle is performed plural times, the phrase “a gas is supplied to the wafer 200” in each step after at least the second cycle means that “a predetermined gas is supplied to a layer formed on the wafer 200, i.e., the uppermost surface of the wafer 200 as a laminated body”. Further, the phrase “a predetermined layer is formed on the wafer 200” means that “a predetermined layer is formed on a layer formed on the wafer 200, i.e., the uppermost surface of the wafer 200 as a laminated body”. This is also the same for the following example.

### (Purging and Returning to Atmospheric Pressure)

The valves 514, 524, and 534 are opened to supply the N₂ gas from the gas supply pipes 510, 520, and 530, respectively, into the process chamber 201 and the N₂ gas is exhausted through the exhaust pipe 231. The N₂ gas acts as a purge gas, and thus, the interior of the process chamber 201 is purged with the inert gas so that the gas or the byproducts remaining in the process chamber 201 are removed from the process chamber 201 (purging). Thereafter, the internal atmosphere of the process chamber 201 is substituted with the inert gas (inert gas substitution), and the internal pressure of the process chamber 201 returns to normal pressure (returning to atmospheric pressure).

### (Boat Unloading and Wafer Discharging)

Thereafter, the seal cap 219 descends by the boat elevator 115 to open the lower end of the reaction tube 203. Then, the processed wafers 200 are unloaded outside the reaction tube 203 through the lower end of the reaction tube 203, with being supported by the boat 217 (boat unloading). Thereafter, the processed wafers 200 are discharged from the boat 217 (wafer discharging).

FIGS. 5A to 5F are views illustrating a technique of forming a pattern on a substrate through a double patterning method. First, a hard mask 601 is formed on the wafer 200, a first resist solvent 602a is applied on the hard mask 601 (FIG. 5A), and a first resist pattern 603a is formed through selective exposure, development, or the like (FIG. 5B). Bottom anti-reflective coating (BARC) 605a may be formed for the selective exposure, development, or the like. Next, a barrier film (protective film) 604 is formed on the first resist pattern 603a and on the hard mark 601 where the first resist pattern has not been formed (FIG. 5C). Further, a second resist solution 602b is applied onto the barrier film 604 (FIG. 5D), and a second resist pattern 603b is formed at a position different from a position where the first resist pattern 603a has been formed through selective exposure, development, or the like (FIG. 5E). Finally, the barrier film 604 is removed through a wet etching method or a dry etching method. By performing a series of these processes, it is possible to form a pattern with a resolution exceeding a limit resolution of lithography on the wafers 200. A TiN film formed in this embodiment may be used as the hard mask 601. Also, the TiN film formed in this embodiment may be used as the barrier film 604.

### (3) Effects of the Present Embodiment

According to this embodiment, one or more effects are provided as described below.

(A) Since C, N, and H, which are the components resulting from an organic source gas, are introduced to a TiN film by forming the TiN film using the halogen-based source gas and the organic source gas as a Ti-containing gas, film density can be lowered and a film formation rate can be increased. When film density is lowered, film stress is lowered. Thus, it is possible to lower the film stress of the finally obtained TiN film by adjusting a supply flow rate and/or a supply time of the organic source gas in forming the TiN film by using the halogen-based Ti-containing gas and the organic source gas as the Ti-containing gas.

(B) Controllability of the film stress of the TiN film can be increased by increasing controllability of atom concentration of each element (Ti, N, C, H, Cl, or the like) included in the finally obtained TiN film, by adjusting a supply flow rate and a supply time of the organic source gas. For example, in forming the TiN film by using the halogen-based source gas and the organic source gas as the Ti-containing gas, the supply flow rate and/or the supply time of the organic source gas can be adjusted such that atom concentration of the elements (C, H, and N) other than Ti resulting from the organic Ti-containing gas is higher than atom concentration of the element (Cl) other than Ti resulting from the halogen-based source gas, so that it is possible to lower film density of the TiN film, to increase a film formation rate, and to lower the film stress.

(C) It is possible to control crystallinity of the TiN film by using the halogen-based source gas and the organic source gas as the Ti-containing gas. The crystallinity of the TiN film can be changed to be close to an amorphous state by adjusting the supply flow rate and/or the supply time of the organic source gas such that atom concentration of the elements (C, H, and N) other than Ti resulting from the organic source gas is higher than atom concentration of the element (Cl) other than Ti resulting from the halogen-based source gas, so that it is possible to increase barrier properties.

(D) After the first Ti-containing layer is first formed by using the organic source gas, the second Ti-containing layer is formed by using the halogen-based source gas, so that wettability of the substrate can be enhanced or surface energy of crystal nucleus can be lowered to obtain the effect of improving the surface roughness of the film.

(E) In forming a film, when a layer including a metal element among elements forming a primary composition of the film to be formed is formed on the substrate, for example, gases having different molecular structures (chemical structures) from each other, like the organic source gas and the halogen-based source gas, are selected as metal-containing source gases to be used. Thus, a composition ratio of each element resulting from each source gas included in the film formed on the substrate can be adjusted (controlled, modulated, or tuned) and a threshold voltage can be adjusted, and thus, a work function can be controlled (adjusted, modulated, or tuned).

(F) It is possible to increase work function controllability of the TiN film by increasing controllability of atom concentration of each element (Ti, N, C, H, Cl, or the like) included in the finally obtained TiN film, by adjusting a supply flow rate and a supply time of the organic source gas.

The above-described effects can be obtained in the same manner when an organic source gas other than the TDEAT gas is used as a source gas, when a halogen-based source gas other than the TiCl₄ gas is used as a source gas, or even when an N-containing gas other than the NH₃ gas is used as a reaction gas.

Hereinafter, other embodiments will be described. A detailed description of the same part as that of the first embodiment will be omitted and a different part from that of the first embodiment will be described below.

### Second Embodiment of the Present Disclosure

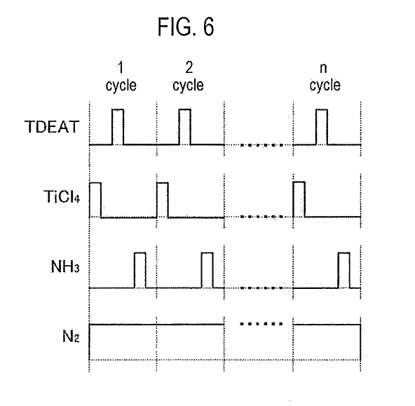

In this embodiment, as illustrated in FIG. 6, a cycle of a halogen-based source (TiCl₄) gas supply step, a residual gas removing step, an organic source (TDEAT) gas supply step, a residual gas removing step, an N-containing (NH₃) gas supply step, and a residual gas removing step is set to one cycle, and n cycles (where n is an integer equal to or greater than 1) are repeatedly performed sequentially in a time-division manner to form a TiN film on the wafer 200.

According to this embodiment, one or more effects are provided as described below.

(A) Since C, N, and H, which are the components resulting from an organic source gas, are introduced to a TiN film by forming the TiN film using the halogen-based source gas and the organic source gas as the Ti-containing gas, film density can be lowered and a film formation rate can be increased. When film density is lowered, film stress is lowered. Thus, it is possible to lower the film stress of the finally obtained TiN film by adjusting a supply flow rate and/or a supply time of the organic source gas in forming the TiN film by using the halogen-based Ti-containing gas and the organic source gas as the Ti-containing gas.

(B) Controllability of the film stress of the TiN film can be increased by increasing controllability of atom concentration of each element (Ti, N, C, H, Cl, or the like) included in the finally obtained TiN film, by adjusting the supply flow rate and/or the supply time of the organic source gas. For example, in forming the TiN film by using the halogen-based source gas and the organic source gas as the Ti-containing gas, the supply flow rate and/or the supply time of the organic source gas can be adjusted such that atom concentration of the elements (C, H, and N) other than Ti resulting from the organic Ti-containing gas is higher than atom concentration of the element (Cl) other than Ti resulting from the halogen-based source gas, so that it is possible to lower film density of the TiN film, increase a film formation rate, and lower the film stress.

(C) It is possible to control crystallinity of the TiN film by using the halogen-based source gas and the organic source gas as the Ti-containing gas. The crystallinity of the TiN film can be changed to be close to an amorphous state by adjusting the supply flow rate and/or the supply time of the organic source gas such that atom concentration of the elements (C, H, and N) other than Ti resulting from the organic source gas is higher than atom concentration of the element (Cl) other than Ti resulting from the halogen-based source gas, so that it is possible to increase barrier properties.

(D) In forming a film, when a layer including a metal element among elements forming a primary composition of the film to be formed is formed on the substrate, for example, gases having different molecular structures (chemical structures) from each other, like the organic source gas and the halogen-based source gas, are selected as metal-containing source gases to be used. Thus, a composition ratio of each element resulting from each source gas included in the film formed on the substrate can be adjusted (controlled, modulated, or tuned) and a threshold voltage can be adjusted, and thus, a work function can be controlled (adjusted, modulated, or tuned).

(E) It is possible to increase work function controllability of the TiN film by increasing controllability of atom concentration of each element (Ti, N, C, H, Cl, or the like) included in the finally obtained TiN film, by adjusting the supply flow rate and/or the supply time of the organic source gas.

### Third Embodiment of the Present Disclosure

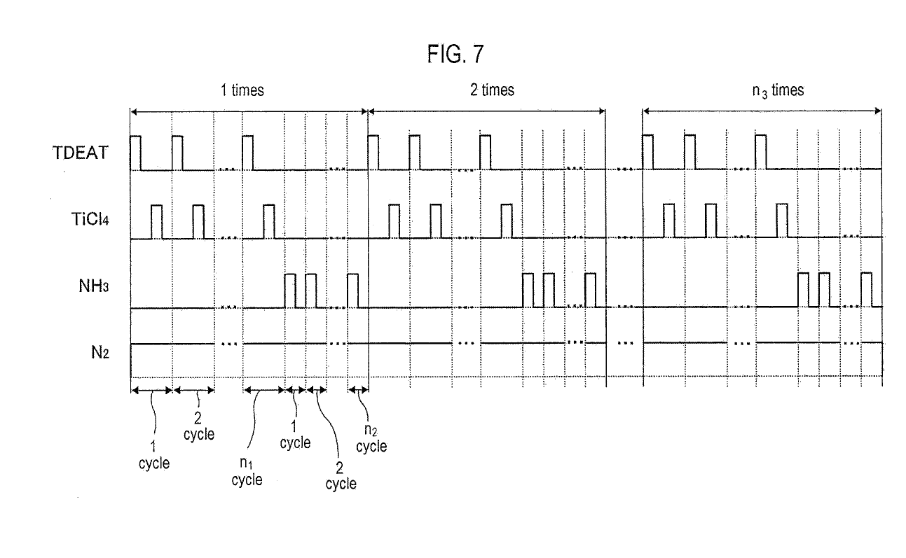

In this embodiment, as illustrated in FIG. 7, a cycle of an organic source (TDEAT) gas supply step, a residual gas removing step, a halogen-based source (TiCl₄) gas supply step, and a residual gas removing step is set to one cycle and n₁ cycles (where n₁ is an integer equal to or greater than 1) are performed sequentially in a time-division manner; and a cycle of an N-containing (NH₃) gas supply step and a residual gas removing step is set to one cycle and n₂ cycles (where n₂ is an integer equal to or greater than 1) are performed; and these are repeatedly performed n₃ times (where n₃ is an integer equal to or greater than 1) to form a TiN film on the wafer 200.

According to this embodiment, one or more effects are provided as described below.

(A) Since C, N, and H, which are the components resulting from an organic source gas, are introduced to a TiN film by forming the TiN film using the halogen-based source gas and the organic source gas as the Ti-containing gas, film density can be lowered and a film formation rate can be increased. When film density is lowered, film stress is lowered. Thus, it is possible to lower the film stress of the finally obtained TiN film by adjusting the supply flow rate and/or the supply time of the organic source gas in forming the TiN film by using the halogen-based Ti-containing gas and the organic source gas as the Ti-containing gas.

(B) Controllability of the film stress of the TiN film can be increased by increasing controllability of atom concentration of each element (Ti, N, C, H, Cl, or the like) included in the finally obtained TiN film, by adjusting the supply flow rate and/or the supply time of the organic source gas. For example, in forming the TiN film by using the halogen-based source gas and the organic source gas as the Ti-containing gas, the supply flow rate and/or the supply time of the organic source gas can be adjusted such that atom concentration of the elements (C, H, and N) other than Ti resulting from the organic Ti-containing gas is higher than atom concentration of the element (Cl) other than Ti resulting from the halogen-based source gas, so that it is possible to lower film density of the TiN film, increase a film formation rate, and lower the film stress.

(C) It is possible to control crystallinity of the TiN film by using the halogen-based source gas and the organic source gas as the Ti-containing gas. The crystallinity of the TiN film can be changed to be close to an amorphous state by adjusting the supply flow rate and/or the supply time of the organic source gas such that atom concentration of the elements (C, H, and N) other than Ti resulting from the organic source gas is higher than atom concentration of the element (Cl) other than Ti resulting from the halogen-based source gas, so that it is possible to increase barrier properties.

(D) After the first Ti-containing layer is first formed by using the organic source gas, the second Ti-containing layer is formed by using the halogen-based source gas, so that wettability of the substrate can be enhanced or surface energy of crystal nucleus can be lowered to obtain the effect of improving surface roughness of the film.

(E) In forming a film, when a layer including a metal element among elements forming a primary composition of the film to be formed is formed on the substrate, for example, gases having different molecular structures (chemical structures) from each other, like the organic source gas and the halogen-based source gas, are selected as metal-containing source gases to be used. Thus, a composition ratio of each element resulting from each source gas included in the film formed on the substrate can be adjusted (controlled, modulated, or tuned) and a threshold voltage can be adjusted, and thus, a work function can be controlled (adjusted, modulated, or tuned).

(F) It is possible to increase work function controllability of the TiN film by increasing controllability of atom concentration of each element (Ti, N, C, H, Cl, or the like) included in the finally obtained TiN film, by adjusting the supply flow rate and/or the supply time of the organic source gas.

(G) Since the cycle including the N-containing gas supply step is performed as a cycle different from the cycle including the organic-source gas supply step, concentration ratios of C and N can be independently controlled, thus further increasing controllability.

### Fourth Embodiment of the Present Disclosure

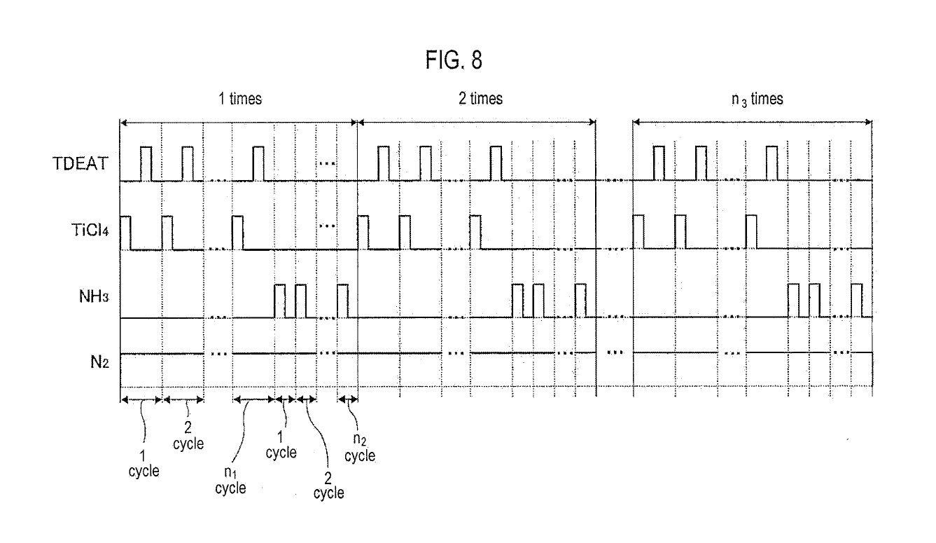

In this embodiment, as illustrated in FIG. 8, a cycle of a halogen-based source (TiCl₄) gas supply step, a residual gas removing step, an organic source (TDEAT) gas supply step, and a residual gas removing step is set to one cycle and n₁ cycles (where n₁ is an integer equal to or greater than 1) are performed sequentially in a time-division manner; and a cycle of an N-containing (NH₃) gas supply step and a residual gas removing step is set to one cycle and n₂ cycles (where n₂ is an integer equal to or greater than 1) are performed; and these are repeatedly performed n₃ times (where n₃ is an integer equal to or greater than 1) to form a TiN film on the wafer 200.

According to this embodiment, one or more effects are provided as described below.

(A) Since C, N, and H, which are the components resulting from an organic source gas, are introduced to a TiN film by forming the TiN film using the halogen-based source gas and the organic source gas as the Ti-containing gas, film density can be lowered and a film formation rate can be increased. When film density is lowered, film stress is lowered. Thus, it is possible to lower the film stress of the finally obtained TiN film by adjusting the supply flow rate and/or the supply time of the organic source gas in forming the TiN film by using the halogen-based Ti-containing gas and the organic source gas as the Ti-containing gas.

(B) Controllability of the film stress of the TiN film can be increased by increasing controllability of atom concentration of each element (Ti, N, C, H, Cl, or the like) included in the finally obtained TiN film, by adjusting the supply flow rate and/or the supply time of the organic source gas. For example, in forming the TiN film by using the halogen-based source gas and the organic source gas as the Ti-containing gas, the supply flow rate and/or the supply time of the organic source gas can be adjusted such that atom concentration of the elements (C, H, and N) other than Ti resulting from the organic Ti-containing gas is higher than atom concentration of the element (Cl) other than Ti resulting from the halogen-based source gas, so that it is possible to lower film density of the TiN film, increase a film formation rate, and lower the film stress.

(C) It is possible to control crystallinity of the TiN film by using the halogen-based source gas and the organic source gas as the Ti-containing gas. The crystallinity of the TiN film can be changed to be close to an amorphous form by adjusting the supply flow rate and/or the supply time of the organic source gas such that atom concentration of the elements (C, H, and N) other than Ti resulting from the organic source gas is higher than atom concentration of the element (Cl) other than Ti resulting from the halogen-based source gas, so that it is possible to increase barrier properties.

(D) In forming a film, when a layer including a metal element among elements forming a primary composition of the film to be formed is formed on the substrate, for example, gases having different molecular structures (chemical structures) from each other, like the organic source gas and the halogen-based source gas, are selected as metal-containing source gases to be used. Thus, a composition ratio of each element resulting from each source gas included in the film formed on the substrate can be adjusted (controlled, modulated, or tuned) and a threshold voltage can be adjusted, and thus, a work function can be controlled (adjusted, modulated, or tuned).

(E) It is possible to increase work function controllability of the TiN film by increasing controllability of atom concentration of each element (Ti, N, C, H, Cl, or the like) included in the finally obtained TiN film, by adjusting the supply flow rate and/or the supply time of the organic source gas.

(F) Since the cycle including the N-containing gas supply step is performed as a cycle different from the cycle including the organic-source gas supply step, concentration ratios of C and N can be independently controlled, thus further increasing controllability.

### Fifth Embodiment of the Present Disclosure

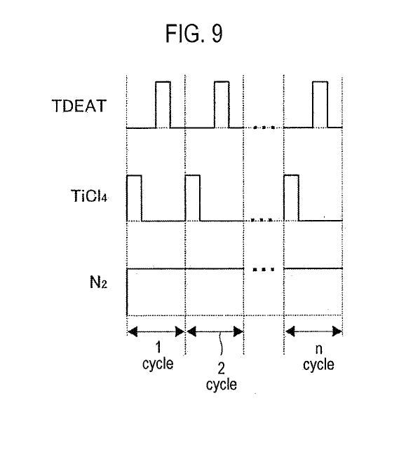

In this embodiment, as illustrated in FIG. 9, a cycle of a halogen-based source (TiCl₄) gas supply step, a residual gas removing step, an organic source (TDEAT) gas supply step, and a residual gas removing step is set to one cycle, and n cycles (where n is an integer equal to or greater than 1) are repeatedly performed sequentially in a time-division manner to form a TiC film (titanium carbide film) on the wafer 200. Further, in this sequence, the N contained in the TDEAT gas may remain in the film. Thus, the film may be a substantial TiCN film (titanium carbonitride film). The film may be called a TiC(N) film or a Ti(C)N film.

According to this embodiment, one or more effects are provided as described below.

(A) Since C, N, and H, which are the components resulting from an organic source gas, are introduced to a Ti(C)N film by forming the Ti(C)N film using the halogen-based source gas and the organic source gas as the Ti-containing gas, film density can be lowered and a film formation rate can be increased. When film density is lowered, film stress is lowered. Thus, it is possible to lower the film stress of the finally obtained Ti(C)N film by adjusting the supply flow rate and/or the supply time of the organic source gas in forming the Ti(C)N film by using the halogen-based Ti-containing gas and the organic source gas as the Ti-containing gas.

(B) Controllability of the film stress of the TiC film can be increased by increasing controllability of atom concentration of each element (Ti, N, C, H, Cl, or the like) included in the finally obtained Ti(C)N film, by adjusting the supply flow rate and/or the supply time of the organic source gas. For example, in forming the Ti(C)N film by using the halogen-based source gas and the organic source gas as the Ti-containing gas, the supply flow rate and/or the supply time of the organic source gas can be adjusted such that atom concentration of the elements (C, H, and N) other than Ti resulting from the organic Ti-containing gas is higher than atom concentration of the element (Cl) other than Ti resulting from the halogen-based source gas, so that it is possible to lower film density of the Ti(C)N film, increase a film formation rate, and lower the film stress.

(C) It is possible to control crystallinity of the Ti(C)N film by using the halogen-based source gas and the organic source gas as the Ti-containing gas. The crystallinity of the Ti(C)N film can be changed to be close to an amorphous state by adjusting the supply flow rate and/or the supply time of the organic source gas such that atom concentration of the elements (C, H, and N) other than Ti resulting from the organic source gas is higher than atom concentration of the element (Cl) other than Ti resulting from the halogen-based source gas, so that it is possible to increase barrier properties.

(D) In forming a film, when a layer including a metal element among elements forming a primary composition of the film to be formed is formed on the substrate, for example, gases having different molecular structures (chemical structures) from each other, like the organic source gas and the halogen-based source gas, are selected as metal-containing source gases to be used. Thus, a composition ratio of each element resulting from each source gas included in the film formed on the substrate can be adjusted (controlled, modulated, or tuned) and a threshold voltage can be adjusted, and thus, a work function can be controlled (adjusted, modulated, or tuned).

(E) It is possible to increase work function controllability of the TiC film by increasing controllability of atom concentration of each element (Ti, N, C, H, Cl, or the like) included in the finally obtained Ti(C)N film, by adjusting the supply flow rate and/or the supply time of the organic source gas.

(F) Crystallization is progressed when the TiN film is formed by using the N-containing gas such as the NH₃ gas. Therefore, the crystallinity of the Ti(C)N film can be changed to be close to an amorphous state by forming the Ti(C)N film without using the N-containing gas, thereby increasing barrier properties.

### Sixth Embodiment of the Present Disclosure

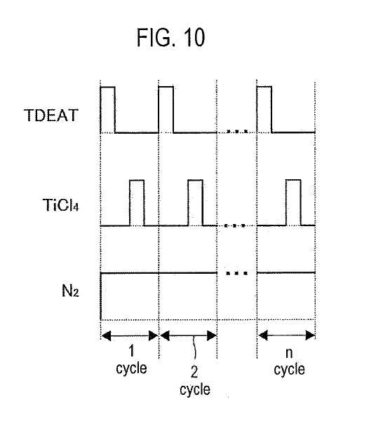

In this embodiment, as illustrated in FIG. 10, a cycle of an organic source (TDEAT) gas supply step, a residual gas removing step, a halogen-based source (TiCl₄) gas supply step, and a residual gas removing step is set to one cycle, and n cycles (where n is an integer equal to or greater than 1) are repeatedly performed sequentially in a time-division manner to form a TiC film (titanium carbide film) on the wafer 200. Further, in this sequence, the N contained in the TDEAT gas may remain in the film. Thus, the film may be a substantial TiCN film (titanium carbonitride film). The film may be called a TiC(N) film or a Ti(C)N film.

According to this embodiment, one or more effects are provided as described below.

(A) Since C, N, and H, which are the components resulting from an organic source gas, are introduced to a Ti(C)N film by forming the Ti(C)N film using the halogen-based source gas and the organic source gas as the Ti-containing gas, film density can be lowered and a film formation rate can be increased. When film density is lowered, film stress is lowered. Thus, it is possible to lower the film stress of the finally obtained Ti(C)N film by adjusting the supply flow rate and/or the supply time of the organic source gas in forming the Ti(C)N film by using the halogen-based Ti-containing gas and the organic source gas as the Ti-containing gas.

(B) Controllability of the film stress of the TiC film can be increased by increasing controllability of atom concentration of each element (Ti, N, C, H, Cl, or the like) included in the finally obtained Ti(C)N film, by adjusting a supply flow rate and/or a supply time of the organic source gas. For example; in forming the Ti(C)N film by using the halogen-based source gas and the organic source gas as the Ti-containing gas, the supply flow rate and/or the supply time of the organic source gas can be adjusted such that atom concentration of the elements (C, H, and N) other than Ti resulting from the organic Ti-containing gas is higher than atom concentration of the element (Cl) other than Ti resulting from the halogen-based source gas, so that it is possible to lower film density of the Ti(C)N film, increase a film formation rate, and lower the film stress.

(C) It is possible to control crystallinity of the Ti(C)N film by using the halogen-based source gas and the organic source gas as the Ti-containing gas. The crystallinity of the Ti(C)N film can be changed to be close to an amorphous state by adjusting the supply flow rate and/or the supply time of the organic source gas such that atom concentration of the elements (C, H, and N) other than Ti resulting from the organic source gas is higher than atom concentration of the element (Cl) other than Ti resulting from the halogen-based source gas, so that it is possible to increase barrier properties.

(D) After the first Ti-containing layer is first formed by using the organic source gas, the second Ti-containing layer is formed by using the halogen-based source gas, so that wettability of the substrate can be enhanced or surface energy of crystal nucleus can be lowered to obtain the effect of improving surface roughness of the film.

(E) In forming a film, when a layer including a metal element among elements forming a primary composition of the film to be formed is formed on the substrate, for example, gases having different molecular structures (chemical structures) from each other, like the organic source gas and the halogen-based source gas, are selected as metal-containing source gases to be used. Thus, a composition ratio of each element resulting from each source gas included in the film formed on the substrate can be adjusted (controlled, modulated, or tuned) and a threshold voltage can be adjusted, and thus, a work function can be controlled (adjusted, modulated, or tuned).

(F) It is possible to increase work function controllability of the Ti(C)N film by increasing controllability of atom concentration of each element (Ti, N, C, H, Cl, or the like) included in the finally obtained Ti(C)N film, by adjusting a supply flow rate and/or a supply time of the organic source gas.

(G) Crystallization is progressed when the TiN film is formed by using the N-containing gas such as the NH₃ gas. Therefore, the crystallinity of the Ti(C)N film can be changed to be close to an amorphous state by forming the Ti(C)N film without using the N-containing gas, thereby increasing barrier properties.

Hereinafter, experimental examples are illustrated, but the present disclosure is not limited thereto.

### Experimental Example 1

In this experimental example, a Ti(C)N film was formed on the wafer 200 by using the sequence of FIG. 9 of the above-described fifth embodiment by using a TiCl₄ gas as a halogen-based source gas and a TDEAT gas as an organic source gas.

### Experimental Example 2

In this experimental example, a process of supplying an NH3 gas as an N-containing gas was added to Experimental Example 1. Specifically, a TiN film was formed on the wafer 200 by using the sequence of FIG. 6 of the above-described second embodiment by using a TiCl₄ gas as a halogen-based source gas, a TDEAT gas as an organic source gas, and an NH₃ gas, which is an N-containing gas, as a reaction gas.

### Comparative Example

In a comparative example, a TiN film was formed on the wafer 200 by alternately supplying a TiCl₄ gas as a halogen-based source gas, and a NH₃ gas, which is an N-containing gas, as a reaction gas.

The process conditions in Experimental Examples 1 and 2 were set as follows.

Internal temperature of process chamber: 200 to 400 degrees C.

Internal pressure of process chamber: 20 to 1330 Pa

Supply flow rate of TiCl₄ gas: 10 to 200 sccm

Supply flow rate of TDEAT gas: 10 to 200 sccm

Supply flow rate of N₂ gas: 1 to 2000 sccm

Supply flow rate of NH₃ gas: 300 to 10000 sccm

Irradiation time of TiCl₄ gas: 5 seconds

Irradiation time of TDEAT gas: 10 seconds

Irradiation time of NH₃ gas: 20 seconds

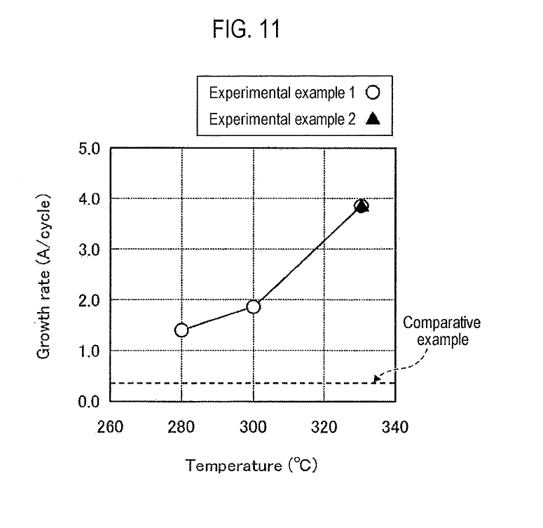

FIG. 11 is a view illustrating film formation rates (Growth rate) of Experimental Example 1, Experimental Example 2, and Comparative Example. The circular mark (∘) indicates results of cases in which an internal temperature of a process chamber was set to 280 degrees C., 300 degrees C., and 330 degrees C. in Experimental Example 1, and the triangular mark (▴) indicates a result of a case in which an internal temperature of the process chamber was set to 330 degrees C. in Experimental Example 2. The dotted line indicates Comparative Example. It can be seen that a film formation rate of the TiN film in Comparative Example was about 0.3 A/cycle, and the TiN films of Experimental Example 1 and Experimental Example 2 had higher film formation rates, regardless of temperature, compared with Comparative Example. Also, in Experimental Example 1, it can be seen that the film formation rate is gradually increased as the temperature is increased.

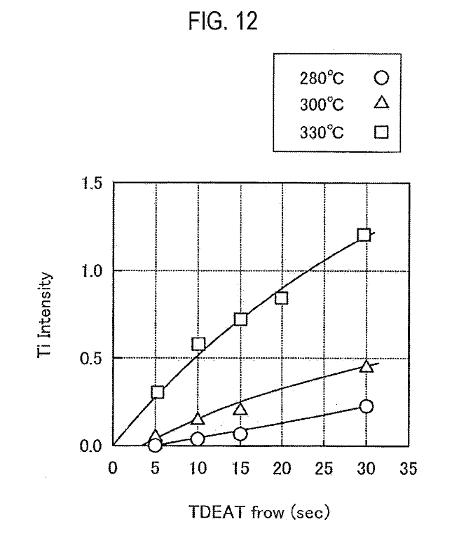

FIG. 12 is a view illustrating a relationship between a supply time of the TDEAT gas and Ti intensity. The circular mark (∘), the triangular mark (Δ), and the quadrangular mark (□) indicate results of cases in which the internal temperature of the process chamber was set to 280 degrees C., 300 degrees C., and 330 degrees C., respectively. As the supply time of the TDEAT gas is increased, a value of the Ti intensity is increased, regardless of temperature. That is, it can be seen that, even though the supply time of the TDEAT gas is lengthened, the TDEAT gas is not saturated.

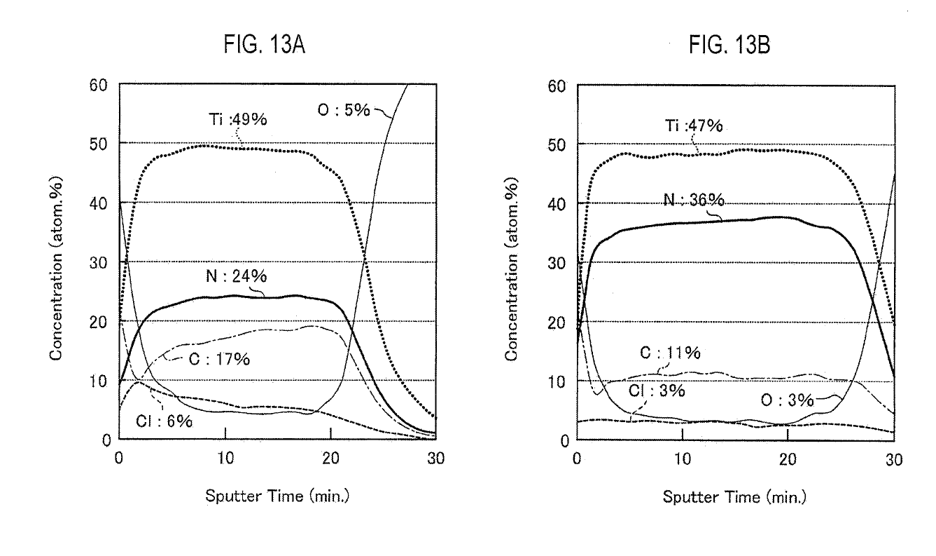

FIG. 13A illustrates a composition ratio of the TiN film formed in Experimental Example 1, and FIG. 13B illustrates a composition ratio of the TiN film formed in Experimental Example 2.

As illustrated in FIGS. 13A and 13B, it can be seen that ratios of C and Cl of the TiN film formed in Experimental Example 2 were reduced while N was increased due to the supply of the NH₃ gas, compared with the TiN film formed in Experimental Example 1. That is, it can be seen that the concentration of C or N of the film can be controlled by the presence or absence of supply of the NH₃ gas, and thus, the content of Ti is also relatively large.

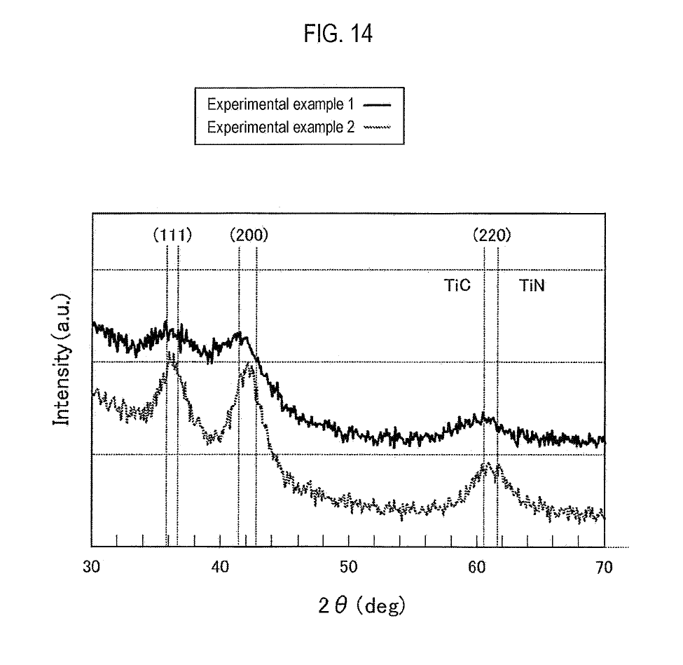

FIG. 14 is a view illustrating crystallinity of the TiN films formed in Experimental Examples 1 and 2.

It can be seen that the TiN film formed in Experimental Example 1 has a crystal peak of TiC, but the crystal peak is weak and that the TiN film is a relatively amorphous film. In contrast, the TiN film formed in Experimental Example 2 has a relatively strong crystal peak, and the crystal peak is shifted toward TiN. That is, it can be seen that crystallinity can be changed by the presence or absence of supply of the NH₃ gas.

When the TiN film is formed by using a halogen-based source gas and an N-containing gas as in Comparative Example, crystal of a columnar structure is formed in many cases. However, when the TiN film is used as a barrier metal, the film having the columnar structure has weak barrier properties against diffusion from an upper layer thereof. In contrast, as in Experimental Example 1 or Experimental Example 2, crystallinity can be changed to be close to an amorphous state by using the organic source gas (preferably, an amine-based source gas). Thus, it is considered to be able to increase the barrier properties.

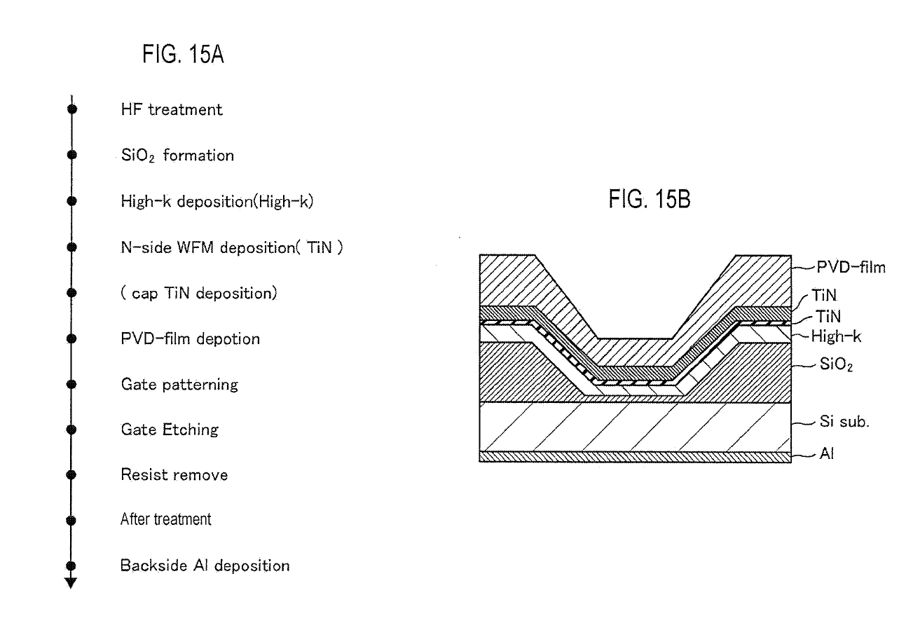

FIGS. 15A and 15B are flow diagrams illustrating a method for manufacturing a capacitor used for calculating a work function.

As illustrated in FIGS. 15A and 15B, a MOS capacitor was manufactured by using the film formation sequence in the foregoing embodiments. First, after an HF treatment was performed on the wafer 200 as a semiconductor silicon substrate, a silicon oxide film (SiO₂ film) was formed, a high dielectric constant (high-k) film as a gate insulating film was formed, and a TiN film was formed thereon by using the processing furnace 202 of the substrate processing apparatus 10. Further, a cap-TiN film was formed thereon, a film was formed through a physical vapor deposition (PVD) method, and backside aluminum (Al) was formed through gate patterning, gate etching, resist removing, and heat treatment.

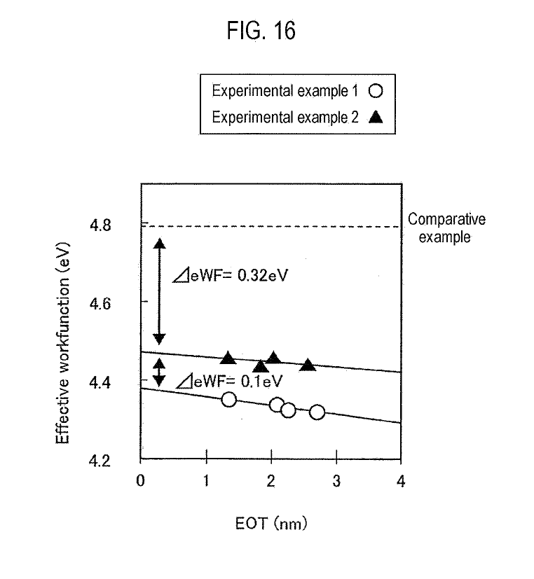

FIG. 16 illustrates that effective work functions (EWF) of equivalent oxide thicknesses (EOT) of the capacitors obtained by Experimental Example 1 and Experimental Example 2 were plotted on the graph to calculate work functions.

As for the EWFs of the TiN film calculated in FIG. 16, the EWF of the TiN film of Comparative Example was about 4.8 eV, while that of the TiN film manufactured according to Experimental Example 1 was 4.38 eV and that of the TiN film manufactured according to Experimental Example 2 was 4.48 eV. That is, it can be seen that the EWF of the TiN film can be increased by about 0.1 eV by supplying the NH₃ gas. In other words, the work function or crystallinity of the TiN film could be controlled through the process of Experimental Example 1 or Experimental Example 2.

### Other Embodiments of the Present Disclosure

The foregoing embodiments may be appropriately combined and used. Further, the present disclosure is not limited to the foregoing embodiments and may be variously modified without departing from the spirit of the present disclosure.

The example of using Ti as a metal element has been described in the foregoing embodiments. However, the present disclosure is not limited thereto and may be appropriately applicable to a case in which any one film selected from a group including a nitride film, an oxide film, a carbide film, and a boride film including elements such as tantalum (Ta), tungsten (W), cobalt (Co), yttrium (Y), ruthenium (Ru), aluminum (Al), hafnium (Hf), zirconium (Zr), molybdenum (Mo), or silicon (Si), which are elements other than Ti, or a composite film thereof is formed.

In case of forming a film including the above-described elements, it is possible to use a Ta-containing gas, a W-containing gas, a Co-containing gas, an Y-containing gas, a Ru-containing gas, an Al-containing gas, a Hf-containing gas, a Zr-containing gas, a Mo-containing gas, a Si-containing gas, or the like, in addition to the Ti-containing gas, as a source gas.

In case of forming a film including the above-described elements, it is also possible to use, for example, titanium tetrafluoride (TiF₄), tantalum pentachloride (TaCl₅), tantalum pentafluoride (TaF₅), tungsten hexachloride (WCl₆), tungsten hexafluoride (WF₆), cobalt dichloride (CoCl₂), cobalt difluoride (CoF₂), yttrium trichloride (YCl₃), yttrium trifluoride (YF₃), ruthenium trichloride (RuCl₃), ruthenium trifluoride (RuF₃), aluminum trichloride (AlCl₃), aluminum trifluoride (AlF₃), hafnium tetrachloride (HfCl₄), hafnium tetrafluoride (HfF₄), zirconium tetrachloride (ZrCl₄), zirconium tetrafluoride (ZrF₄), tetrachlorosilane, i.e., silicon tetrachloride (SiCl₄, abbreviation: STC)), dichlorosilane (SiH₂Cl₂, abbreviation: DCS), monochlorosilane (SiH₃Cl, abbreviation: MCS), hexachlorodisilane (Si₂Cl₆, abbreviation: HCDS), or the like, in addition to TiCl₄, as a halogen-based source gas that is an inorganic source gas.

In case of forming a film including the above-described elements, it is possible to use, for example, tetrakisdimethylaminotitanium (Ti[N(CH₃)₂]₄, abbreviation: TDMAT), pentaethoxytantalum (Ta(OC₂H₅)₅, abbreviation: PET), trimethylaluminum ((CH₃)₃Al, abbreviation: TMA), tetrakisethylmethylaminohafnium (Hf[N(CH₃)CH₂CH₃]₄, abbreviation: TEMAH), tetrakisdimethylaminohafnium (Hf[N(CH₃)₂]₄,TDMAH), tetrakisdiethylaminohafnium (Hf[N(C₂H₅)₂]₄, abbreviation: TDEAH), tetrakisethylmethylaminozirconium (Zr[N(CH₃)CH₂CH₃]₄, abbreviation: TEMAZ), tetrakisdimethylaminozirconium (Zr[N(CH₃)₂]₄,TDMAZ), tetrakisdiethylaminozirconium (Zr[N(C₂H₅)₂]₄, abbreviation: TDEAZ), trisdimethylaminocyclopentadienylzirconium ((C₅H₅)Zr[N(CH₃)₂]₃), tetrakis (dimethylamino)silane (Si[N(CH₃)₂]₄, abbreviation: 4DMAS), tris(dimethylamino)silane Si[N(CH₃)₂]₃H, abbreviation: 3DMAS), bis(diethylamino)silane (Si[N(C₂H₅)₂]₂H₂, abbreviation: BDEAS), bis(tertiarybutylamino)silane (SiH₂[NH(C₄H₉)]₂, abbreviation: BTBAS), bis(tertiarybutylimino)bis(tertiarybutylamino)tungsten ((C₄H₉NH)₂ W(C₄H₉N)₂,), tungstenhexacarbonyl (W(CO)₆), bis(ethylcyclopentadienyl)cobalt (C₁₄H₁₈Co), cobalthexacarbonyl (CoCO)₆), tris(butylcyclopentadienyl)yttrium (Y(C₅H₄CH₂(CH₂)₂CH₃)₃), bis(ethylcyclopentadienyl)ruthenium (C₁₄H₁₈Ru), or the like, in addition to TDEAT, as an organic source gas.

In case of forming a film including the above-described elements, it is possible to use, as a reaction gas, a gas containing N—H bond such as, e.g., nitrogen (N₂), nitrous oxide (N₂O), a diagen (N₂H₂) gas, a hydrazine (N₂H₄) gas, or an N₃H₈ gas, in addition to NH3. Also, in addition to the above-described gas, as gases containing the N—H bond, an organic hydrazine-based gas, for example, a methylhydrazine-based gas such as a monomethylhydrazine ((CH₃)HN₂H₂, abbreviation: MMH) gas, a dimethylhydrazine ((CH₃)₂N₂H₂, abbreviation: DMH) gas, or a trimethylhydrazine ((CH₃)₂N₂(CH₃)H, abbreviation: TMH) gas, or an ethyl hydrazine-based gas such as an ethyihydrazine ((C₂H₅)HN₂H₂, abbreviation: EH) gas may be used. Also, an ethylamine-based gas such as a triethylamine ((C₂H₅)₃N, abbreviation: TEA) gas, a diethylamine ((C₂H₅)₂NH, abbreviation: DEA) gas, or a monoethylamine (C₂H₅NH₂, abbreviation: MEA) gas, a methylamine-based gas such as a trimethylamine ((CH₃)₃N, abbreviation: TMA) gas, a dimethylamine ((CH₃)₂NH, abbreviation: DMA) gas, or a monomethylamine (CH₃NH₂, abbreviation: MMA) gas, a propylamine-based gas such as a tripropylamine ((C₃H₇)₃N, abbreviation: TPA) gas, a dipropylamine ((C₃H₇)₂NH, abbreviation: DPA) gas, or a monopropylamine (C₃H₇NH₂, abbreviation: MPA) gas, an isopropylamine-based gas such as a triisopropylamine ([(CH₃)₂CH]₃N, abbreviation: TIPA) gas, a diisopropylamine ([(CH₃)₂CH]₂NH, abbreviation: DIPA) gas, or a monoisopropylamine ((CH₃)₂CHNH₂, abbreviation: MIPA) gas, a butylamine-based gas such as a tributylamine ((C₄H₉)₃N, abbreviation: TBA) gas, a dibutylamine ((C₄H₉)₂NH, abbreviation: DBA) gas, or a monobutylamine (C₄H₉NH₂, abbreviation: MBA) gas, or an isobutylamine-based gas such as a triisobutylamine ([(CH₃)₂CHCH₂]₃N, abbreviation: TIBA) gas, a diisobutylamine ([(CH₃)₂CHCH₂]₂NH, abbreviation: DIBA) gas, or a monoisobutylamine ((CH₃)₂CHCH₂NH₂, abbreviation: MIBA) gas may be used. That is, as an amine-based gas, for example, at least one of the gases represented by composition formula of (C₂H₅)ₓNH₃₋ₓ, (CH₃)ₓNH₃₋ₓ, (C₃H₇)ₓNH₃₋ₓ, [(CH₃)₂CH]ₓNH₃₋ₓ, (C₄H₉)ₓNH₃₋ₓ, [(CH₃)₂CHCH₂]ₓNH₃₋ₓ (where x in the chemical formula denotes an integer ranging from 1 to 3) may be used. When an organic hydrazine-based gas or an amine-based gas is used, reactivity may be increased while C can be introduced into the film. Thus, a work function of the film may be adjusted by controlling concentration of C.

Films containing the above-described elements may include, for example, a tantalum nitride film (TaN film), a tantalum carbide film (TaC film), a tantalum carbonitride film (TaCN film), a tungsten nitride film (WN film), a tungsten carbide film (WC film), a tungsten carbonitride film (WCN film), a cobalt nitride film (CoN film), a cobalt carbide film (CoC film), a cobalt carbonitride film (CoCN film), an yttrium nitride film (YN film), an yttrium carbide film (YC film), an yttrium carbonitride film (YCN film), a ruthenium nitride film (RuN film), a turhenium carbide film (RuC film), a ruthenium carbonitride film (RuCN film), an aluminum nitride film (AlN film), an aluminum carbide film (AlC film), an aluminum carbonitride film (AlCN film), a hafnium nitride film (HfN film), a hafnium carbide film (HfC film), a hafnium carbonitride film (HfCN film), a zirconium nitride film (ZrN film), a zirconium carbide film (ZrC film), a zirconium carbonitride film (ZrCN film), a molybdenum nitride film (MoN film), a molybdenum carbide film (MoC film), a molybdenum carbonitride film (MoCN film), a silicon nitride film (SiN film), a silicon carbide film (SiC film), and a silicon carbonitride film (SiCN film), in addition to the TiN film, the TiC film, and the TiCN film.

Further, in the foregoing embodiment, the example in which the N2 gas is used as an inert gas has been described, but the present disclosure is not limited thereto and a rare gas such as an argon (Ar) gas, a helium (He) gas, a neon (Ne) gas, or a xenon (Xe) gas may be used.

In the foregoing embodiment, an example in which the substrate processing apparatus of a batch type vertical apparatus for processing a plurality of substrates at a time is usded has been described. In the substrate procesing apparatus, a film is formed by using a processing furnace having a structure in which nozzles for supplying a process gas are vertically installed in one reaction tube while an exhaust port is installed below the reaction tube. However, the present disclosure may also be applicable to a case in which a film is formed by using a processing furnace having a different structure. For example, the present disclosure may also be applicable to a case of forming a film by using a processing furnace having a structure in which two reaction tubes (an outer reaction tube is called an outer tube and an inner reaction tube is called an inner tube) having a concentrically circular cross-section are provided. In the processing furnace, a process gas flows from a nozzle vertically installed within the inner tube to an exhaust port which is opened at a location in a sidewall of the outer tube opposite to the nozzle with a substrate interposed therebetween (linearly symmetrical location). In addition, the process gas may be supplied via a gas supply hole opened in a sidewall of the inner tube, rather than being supplied from the nozzle vertically installed within the inner tube. In such a case, the exhaust port opened in the outer tube may be vertically positioned depending on a height at which a plurality of substrates stacked and accommodated in a process chamber are positioned. Further, the shape of the exhaust port may have a hole shape or a slit shape.

Also, in the above-described embodiment, an example of forming a film using a batch type vertical substrate processing apparatus in which a plurality of substrates can be processed at a time has been described. However, the present disclosure is not limited thereto and may be appropriately applicable to a case in which a film is formed using a single-wafer type substrate processing apparatus which can process one or several substrates at a time. In addition, in the above-described embodiment, an example of forming a thin film using a substrate processing apparatus having a hot wall type processing furnace has been described. However, the present disclosure is not limited thereto and may be appropriately applicable to a case in which a film is formed using a substrate processing apparatus having a cold wall type processing furnace. Even in these cases, process conditions may be the same as those in the embodiments described above by way of example.

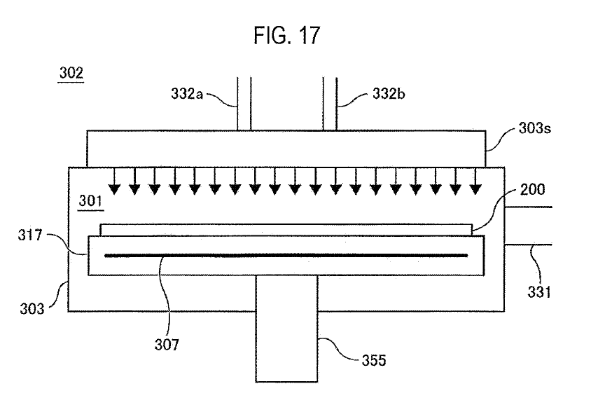

For example, the present disclosure may be appropriately applicable to a case in which a film is formed using a substrate processing apparatus having a processing furnace 302 shown in FIG. 17. The processing furnace 302 includes a process vessel 303 forming a process chamber 301, a shower head 303s supplying a gas in the form of a shower into the process chamber 301, a support table 317 configured to support one or several wafers 200 in a horizontal posture, a rotation shaft 355 configured to support the support table 317 from a bottom end thereof, and a heater 307 installed in the support table 317. An inlet (gas introduction port) of the shower head 303s is connected with a gas supply port 332a for supplying the above-described source gas and a gas supply port 332b for supplying the above-described reaction gas. The gas supply port 332a is connected with a source gas supply system like the source gas supply system in the above-described embodiment. The gas supply port 332b is connected with a reaction gas supply system like the reaction gas supply system in the above-described embodiment. A gas distribution plate for supplying a gas in the form of a shower into the process chamber 301 is installed in an outlet (gas discharging port) of the shower head 303s. An exhaust port 331 for exhausting the interior of the process chamber 301 is installed in the process vessel 303. The exhaust port 331 is connected with an exhaust system like the exhaust system in the above-described embodiment.

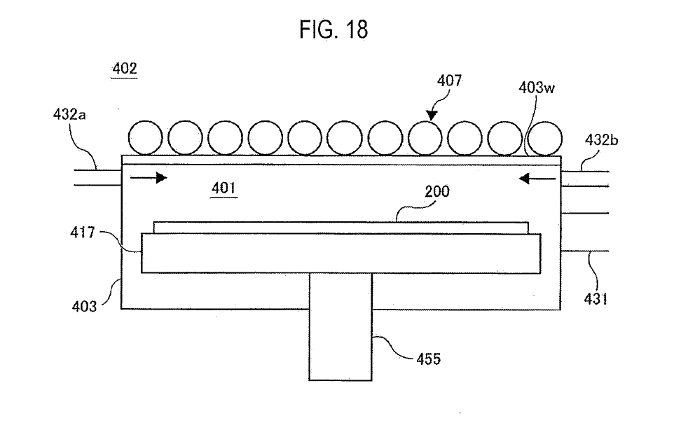

In addition, for example, the present disclosure may be appropriately applicable to a case in which a film is formed using a substrate processing apparatus having a processing furnace 402 shown in FIG. 18. The processing furnace 402 includes a process vessel 403 forming a process chamber 401, a support table 417 configured to support one or several wafers 200 in a horizontal posture, a rotation shaft 455 configured to support the support table 417 from a bottom end thereof, a lamp heater 407 configured to irradiate light toward the wafers 200 in the process vessel 403, and a quartz window 403w allowing the light irradiated from the lamp heater 407 to transmit therethrough. The process vessel 403 is connected with a gas supply port 432a for supplying the above-described source gas and a gas supply port 432b for supplying the above-described reaction gas. The gas supply port 432a is connected with a source gas supply system like the source gas supply system in the above-described embodiment. The gas supply port 432b is connected with a reaction gas supply system like the reaction gas supply system in the above-described embodiment. An exhaust port 431 for exhausting the interior of the process chamber 401 is installed in the process vessel 403. The exhaust port 431 is connected with an exhaust system like the exhaust system in the above-described embodiment.

Even when these substrate processing apparatuses are used, a film forming process can be performed with the same sequence and process conditions as the above-described embodiments and modifications.

The process recipe used for forming theses various kinds of thin films (program in which a process order, process conditions and the like are described) are prepared preferably individually (a plurality of recipes are prepared) according to contents of the substrate processing (a type, a composition ratio, a film quality and a film thickness of a thin film to be formed, a process order, process conditions and the like). In addition, when the substrate processing is initiated, it is preferred that a suitable process recipe is appropriately selected among the plurality of process recipes according to contents of the substrate processing. Specifically, preferably, the plurality of process recipes individually prepared according to the contents of the substrate processing is preferably stored (installed) beforehand in the memory device 121c provided in the substrate processing apparatus via an electrical communication line or a recording medium (e.g., the external memory device 123) in which the corresponding process recipes are recorded. In addition, when the substrate processing is initiated, it is preferred that the CPU 121a provided in the substrate processing apparatus appropriately selects a suitable process recipe among the plurality of process recipes stored in the memory device 121c according to the contents of the substrate processing. With this configuration, multipurpose thin films having a variety of film types, composition ratios, film qualities and film thicknesses can be formed at high reproducibility with one substrate processing apparatus. In addition, it is possible to reduce an operation burden of an operator (a burden of inputting a process order or process conditions by the operator), and to rapidly initiate the substrate processing while avoiding an operation mistake.

Further, the present disclosure may also be realized by, for example, modifying a process recipe of the existing substrate processing apparatus. In case of modifying the process recipe, the process recipe according to the present disclosure may be installed in the existing substrate processing apparatus through an electrical communication line or a recording medium in which the corresponding recipe is recorded, or the process recipe itself may also be modified into a process recipe for the present disclosure by manipulating an input/output device provided in the existing substrate processing apparatus.

### <Aspects of the Present Disclosure>

Hereinafter, preferred aspects of the present disclosure will be supplemented.

### (Supplementary Note 1)

According to one aspect of the present disclosure, there is provided a method of manufacturing a semiconductor device or a substrate processing method, including: forming a metal-containing film including a first element that is a metal element and a second element by performing a predetermined number of times in a time-division manner (asynchronously, intermittently, or in a pulse manner) a cycle including:

supplying an organic metal source gas containing the first element to a substrate;

supplying a halogen-based metal source gas containing the first element to the substrate; and

supplying a reaction gas, which contains the second element and which reacts with the first element, to the substrate,

wherein a value of film stress of the metal-containing film is controlled (adjusted, modulated, or tune) by controlling (adjusting or tuning) at least one value of a supply flow rate and a supply time of the organic metal source gas in the act of supplying an organic metal source gas.

### (Supplementary Note 2)

In the method of manufacturing a semiconductor device or the substrate processing method according to Supplementary Note 1, preferably, the act of supplying an organic metal source gas, the act of supplying a halogen-based metal source gas, and the act of supplying a reaction gas are sequentially performed a predetermined number of times in a time-division manner.

### (Supplementary Note 3)

In the method of manufacturing a semiconductor device or the substrate processing method according to Supplementary Note 1, preferably, the act of supplying a halogen-based metal source gas, the act of supplying an organic metal source gas, and the act of supplying a reaction gas are sequentially performed a predetermined number of times in a time-division manner.

### (Supplementary Note 4)

In the method of manufacturing a semiconductor device or the substrate processing method according to any one of Supplementary Notes 1 to 3, preferably, the metal-containing film is a thin film formed as a hard mask for etching an etching target film formed on the substrate.

### (Supplementary Note 5)

In the method of manufacturing a semiconductor device or the substrate processing method according to any one of Supplementary Notes 1 to 4, preferably, the first element is any one selected from a group consisting of titanium (Ti), tantalum (Ta), tungsten (W), cobalt (Co), yttrium (Y), ruthenium (Ru), aluminum (Al), hafnium (Hf), zirconium (Zr), and molybdenum (Mo), and the second element is nitrogen.

### (Supplementary Note 6)

In the method of manufacturing a semiconductor device and the substrate processing method according to any one of Supplementary Notes 1 to 5, preferably, the film stress of the metal-containing film is controlled by controlling concentration ratios of the second element and carbon included in the metal-containing film.

### (Supplementary Note 7)

According to another aspect of the present disclosure, there is provided a method of manufacturing a semiconductor device or a substrate processing method, including:

forming a metal-containing layer including a first element that is a metal element by performing in a time-division manner (asynchronously, intermittently, or in a pulse manner) a cycle including supplying an organic metal source gas containing the first element to a substrate, and supplying a halogen-based metal source gas containing the first element to the substrate;

supplying a reaction gas, which contains a second element and which reacts with the first element, to the substrate;

wherein each of the act of forming a metal-containing layer and the act of supplying a reaction gas is performed a predetermined number of times to form a metal-containing film including the first element and the second element, and

wherein a value of film stress of the metal-containing film is controlled (adjusted, modulated or tuned) by controlling (adjusting or tuning) at least one value of a supply flow rate and a supply time of the organic metal source gas in the act of supplying an organic metal source gas.

### (Supplementary Note 8)

In the method of manufacturing a semiconductor device or the substrate processing method according to Supplementary Note 7, preferably, the act of supplying an organic metal source gas and the act of supplying a halogen-based metal source gas are sequentially performed a predetermined number of times in a time-division manner.

### (Supplementary Note 9)

In the method of manufacturing a semiconductor device or the substrate processing method according to Supplementary Note 7, preferably, the act of supplying a halogen-based metal source gas and the act of supplying an organic metal source gas are sequentially performed a predetermined number of times in a time-division manner.

### (Supplementary Note 10)

In the method of manufacturing a semiconductor device or the substrate processing method according to any one of Supplementary Notes 7 to 9, preferably, the metal-containing film is a thin film formed as a hard mask for etching an etching target film formed on the substrate.

### (Supplementary Note 11)

In the method of manufacturing a semiconductor device or the substrate processing method according to any one of Supplementary Notes 7 to 10, preferably, the first element is any one selected from a group consisting of titanium (Ti), tantalum (Ta), tungsten (W), cobalt (Co), yttrium (Y), ruthenium (Ru), aluminum (Al), hafnium (Hf), zirconium (Zr), and molybdenum (Mo), and the second element is nitrogen.

### (Supplementary Note 12)

According to another aspect of the present disclosure, there is provided a method of manufacturing a semiconductor device or a substrate processing method, including forming a metal-containing carbide film including a metal element and carbon by performing a predetermined number of times in a time-division manner (asynchronously, intermittently, or in a pulse manner) a cycle including:

supplying an organic metal source gas containing the metal element and carbon to a substrate; and

supplying a halogen-based metal source gas containing the metal element to the substrate,

wherein a value of film stress of the metal-containing carbide film is controlled (adjusted, modulated or tuned) by controlling (adjusting or tuning) at least one value of a supply flow rate and a supply time of the organic metal source gas in the act of supplying an organic metal source gas.

### (Supplementary Note 13)

In the method of manufacturing a semiconductor device or the substrate processing method according to Supplementary Note 12, preferably, the organic metal source gas further contains nitrogen,

wherein the act of supplying an organic metal source gas and the act of supplying a halogen-based metal source gas are performed a predetermined number of times in a time-division manner (asynchronously, intermittently, or in a pulse manner) to form a metal-containing carbonitride film including the metal element, carbon, and nitrogen, and

wherein a value of film stress of the metal-containing carbonitride film is controlled (adjusted, modulated or tuned) by controlling (adjusting or tuning) at least one value of a supply flow rate and a supply time of the organic metal source gas in the act of supplying an organic metal source gas.

### (Supplementary Note 14)

In the method of manufacturing a semiconductor device or the substrate processing method according to Supplementary Note 13, preferably, the film stress of the metal-containing carbonitride film is controlled by controlling concentration ratios of the metal element, carbon, and nitrogen.

### (Supplementary Note 15)

In the method of manufacturing a semiconductor device or the substrate processing method according to any one of Supplementary Notes 12 to 14, preferably, the metal element is any one selected from a group consisting of titanium (Ti), tantalum (Ta), tungsten (W), cobalt (Co), yttrium (Y), ruthenium (Ru), aluminum (Al), hafnium (Hf), zirconium (Zr), and molybdenum (Mo).

### (Supplementary Note 16)

According to another aspect of the present disclosure, there is provided a substrate processing apparatus, including:

a process chamber configured to accommodate a substrate;

a gas supply system configured to supply an organic metal source gas containing a first element that is a metal element, a halogen-based metal source gas containing the first element, and a reaction gas, which contains a second element and which reacts with the first element, to the substrate; and

a control part configured to control the gas supply system such that a metal-containing film including the first element and the second element is formed by performing a predetermined number of times in a time-division manner (asynchronously, intermittently, or in a pulse manner) a cycle of supplying the organic metal source gas to the substrate accommodated in the process chamber, supplying the halogen-based metal source gas to the substrate, and supplying the reaction gas to the substrate, and such that a value of film stress of the metal-containing film is controlled (adjusted, modulated or tuned) by controlling (adjusting or tuning) at least one value of a supply flow rate and a supply time of the organic metal source gas in the act of supplying the organic metal source gas.

### (Supplementary Note 17)

According to another aspect of the present disclosure, there is provided a substrate processing apparatus, including:

a process chamber configured to accommodate a substrate;

a gas supply system configured to supply an organic metal source gas containing a first element that is a metal element, a halogen-based metal source gas containing the first element, and a reaction gas, which contains a second element and which reacts with the first element, to the substrate; and

a control part configured to control the gas supply system such that a metal-containing film including the first element and the second element is formed by performing a predetermined number of times forming a metal layer containing the first element by performing in a time-division manner (asynchronously, intermittently, or in a pulse manner) a cycle of supplying the organic metal source gas to the substrate accommodated in the process chamber and supplying the halogen-based metal source gas to the substrate, and supplying the reaction gas to the substrate, and such that a value of film stress of the metal-containing film is controlled (adjusted, modulated or tuned) by controlling (adjusting or tuning) at least one value of a supply flow rate and a supply time of the organic metal source gas in the act of supplying the organic metal source gas.

### (Supplementary Note 18)

According to another aspect of the present disclosure, there is provided a substrate processing apparatus, including:

a process chamber configured to accommodate a substrate;

a gas supply system configured to supply an organic metal source gas containing a metal element and a halogen-based metal source gas containing the metal element to the substrate; and

a control part configured to control the gas supply system such that a metal-containing carbide film including the metal element and carbon is formed by performing a predetermined number of times in a time-division manner (asynchronously, intermittently, or in a pulse manner) a cycle of supplying the organic metal source gas to the substrate accommodated in the process chamber and supplying the halogen-based metal source gas to the substrate, and such that a value of film stress of the metal-containing carbide film is controlled (adjusted, modulated or tuned) by controlling (adjusting or tuning) at least one value of a supply flow rate and a supply time of the organic metal source gas in the act of supplying the organic metal source gas.

### (Supplementary Note 19)

According to another aspect of the present disclosure, there is provided a program that causes a computer to perform a process and a non-transitory computer-readable recording medium storing the program, the process including a sequence of forming a metal-containing film including a first element that is a metal element and a second element by performing a predetermined number of times in a time-division manner (asynchronously, intermittently, or in a pulse manner) a cycle including;

a sequence of supplying an organic metal source gas containing the first element to a substrate;

a sequence of supplying a halogen-based metal source gas containing the first element to the substrate; and

a sequence of supplying a reaction gas, which contains the second element and which reacts with the first element, to the substrate; and

a sequence of controlling (adjusted, modulated or tuned) a value of film stress of the metal-containing film by controlling (adjusting or tuning) at least one value of a supply flow rate and a supply time of the organic metal source gas in the sequence of supplying an organic metal source gas.

### (Supplementary Note 20)

According to another aspect of the present disclosure, there is provided a program that causes a computer to perform a process and a non-transitory computer-readable recording medium storing the program, the process including a sequence of forming a metal-containing layer including a first element that is a metal element by performing in a time-division manner (asynchronously, intermittently, or in a pulse manner) a cycle including a sequence of supplying an organic metal source gas containing the first element to a substrate, and a sequence of supplying a halogen-based metal source gas containing the first element to the substrate;

a sequence of supplying a reaction gas, which contains a second element and which reacts with the first element, to the substrate;

a sequence of performing a predetermined number of times each of the sequence of forming a metal-containing layer and the sequence of supplying a reaction gas to form a metal-containing film including the first element and the second element; and

a sequence of controlling (adjusted, modulated or tuned) a value of film stress of the metal-containing film by controlling (adjusting or tuning) at least one value of a supply flow rate and a supply time of the organic metal source gas in the sequence of supplying an organic metal source gas.

### (Supplementary Note 21)

According to another aspect of the present disclosure, there is provided a program that causes a computer to perform a process and a non-transitory computer-readable recording medium storing the program, the process including a sequence of forming a metal-containing carbide film including a metal element and carbon by performing a predetermined number of times in a time-division manner (asynchronously, intermittently, or in a pulse manner) a cycle including;

a sequence of supplying an organic metal source gas containing the metal element and carbon to a substrate;

a sequence of supplying a halogen-based metal source gas containing the metal element to the substrate; and

a sequence of controlling (adjusting, modulating, or tuning) a value of film stress of the metal-containing carbide film by controlling (adjusting or tuning) at least one value of a supply flow rate and a supply time of the organic metal source gas in the sequence of supplying an organic metal source gas.

According to the present disclosure in some embodiments, it is possible to provide a technique capable of increasing barrier properties by reducing film stress of a conductive thin film.

As described above, the present disclosure can be employed in, for example, a method of manufacturing a semiconductor device, a substrate processing apparatus such as a substrate wafer or a glass substrate, etc.

While certain embodiments have been described, these embodiments have been presented by way of example only, and are not intended to limit the scope of the disclosures. Indeed, the novel methods and apparatuses described herein may be embodied in a variety of other forms; furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A method of manufacturing a semiconductor device comprising forming a metal-containing film including a first element that is a metal element and a second element by performing a predetermined number of times in a time-division manner a cycle comprising:
supplying an organic metal source gas containing the first element to a substrate;
supplying a halogen-based metal source gas containing the first element to the substrate; and
supplying a reaction gas, which contains the second element and which reacts with the first element, to the substrate,
wherein a value of film stress of the metal-containing film is controlled by controlling at least one value of a supply flow rate and a supply time of the organic metal source gas in the act of supplying an organic metal source gas.

2. The method of claim 1, wherein the act of supplying an organic metal source gas, the act of supplying a halogen-based metal source gas, and the act of supplying a reaction gas are sequentially performed a predetermined number of times in a time-division manner.

3. The method of claim 1, wherein the act of supplying a halogen-based metal source gas, the act of supplying an organic metal source gas, and the act of supplying a reaction gas are sequentially performed a predetermined number of times in a time-division manner.

4. The method of claim 1, wherein the metal-containing film is a thin film formed as a hard mask for etching an etching target film formed on the substrate.

5. The method of claim 1, wherein the first element is any one selected from a group consisting of titanium, tantalum, tungsten, cobalt, yttrium, ruthenium, aluminum, hafnium, zirconium, and molybdenum, and the second element is nitrogen.

6. The method of claim 1, wherein, after the act of supplying an organic metal source gas and the act of supplying a halogen-based metal source gas are performed a plural number of times in a time-division manner, the act of supplying a reaction gas is performed in a time-division manner.

7. The method of claim 1, wherein the film stress of the metal-containing film is controlled by controlling concentration ratios of the second element and carbon included in the metal-containing film.

8. The method of claim 1, wherein the value of film stress of the metal-containing film is controlled by adjusting a ratio between a thickness of a metal-containing layer including the first element resulting from the act of supplying an organic metal source gas and a thickness of a metal-containing layer including the first element resulting from the act of supplying a halogen-based metal source gas.

9. The method of claim 8, wherein the thickness of the metal-containing layer including the first element resulting from the act of supplying an organic metal source gas is larger than the thickness of the metal-containing layer including the first element resulting from the act of supplying a halogen-based metal source gas.

10. The method of claim 1, wherein the value of film stress of the metal-containing film is additionally controlled by controlling at least one value of a supply flow rate and a supply time of the reaction gas in the act of supplying a reaction gas.

11. A non-transitory computer-readable recording medium storing a program that causes a computer to perform a process including a sequence of forming a metal-containing film including a first element that is a metal element and a second element by performing a predetermined number of times in a time-division manner a cycle including;
a sequence of supplying an organic metal source gas containing the first element to a substrate;
a sequence of supplying a halogen-based metal source gas containing the first element to the substrate; and
a sequence of supplying a reaction gas, which contains the second element and which reacts with the first element, to the substrate; and
a sequence of controlling a value of film stress of the metal-containing film by controlling at least one value of a supply flow rate and a supply time of the organic metal source gas in the sequence of supplying an organic metal source gas.
